(19) United States
(12) Patent Application Publication
(10) Pub. No.: US 2011/0108899 A1
(43) Pub. Date: May 12, 2011

(54) FERROELECTRIC ORGANIC MEMORIES WITH ULTRA-LOW VOLTAGE OPERATION

(76) Inventors: Alain Jonas, Louvain-la-Neuve (BE); Zhijun Hu, Louvain-la-Neuve (BE)

(21) Appl. No.: 12/994,934

(22) PCT Filed: May 29, 2009
(86) PCT No.: PCT/EP2009/056656

§ 371 Date: Nov. 29, 2010

(30) Foreign Application Priority Data
May 30, 2008 (GB) 0809840.2

(51) Int. Cl. H01L 29/68; H01L 21/04

(52) U.S. Cl. 257/295; 438/3; 257/E29.17; 257/E21.04

(57) ABSTRACT

A method of manufacturing a patterned ferroelectric polymer memory medium is disclosed, which includes forming an electrode on a substrate; forming a ferroelectric polymer thin film on the electrode; and patterning and orienting the polymer thin film into a plurality of nanostructures by embossing techniques. Also disclosed are two methods which include forming nanofeatures in an interlayer dielectric (ILD) layer deposited on a substrate; forming a ferroelectric polymer thin film on the ILD layer in the nanofeatures; and patterning and orienting the polymer thin film into a plurality of nanostructures by pressing. The patterning process followed by an annealing process promotes specific crystal orientation, which significantly reduces the operation voltage, and increases the signal-to-noise ratio. The invention also covers devices made of a ferroelectric polymer layer oriented by such an embossing method and the use of such devices at a coercive field of 10 MV/m or less.

### FIELD OF THE INVENTION

The present invention relates to the field of memory device and recording medium wfor use in microelectronics. In particular, the present invention relates to polymer material based, non-volatile ferroelectric memory devices, their manufacturing and their use.

### BACKGROUND ART

It is known that ferroelectric thin films can be used as memory media for memory or data storage applications. Ferroelectric memory devices notably provide non-volatile capability, relatively low voltage operation, and fast switching speed, compared to other currently used memory or data storage media. One way to construct an electrically addressable ferroelectric memory device consists of combining a ferroelectric capacitor and a transistor (1C1T, a device known as FeRAM (ferroelectric random access memory)). Another way consists in integrating arrays of ferroelectric capacitors. FeRAMs exhibit the endurance of dynamic random access memories (DRAM), the fast write and read speed of static random access memories (SRAM), and the non-volatile capability of Flash memories. Ferroelectric memory devices made of capacitor arrays have the further advantage of possible fabrication on VLSI chips, and of fast switching speed. Ferroelectric thin films have also been considered for mechanically addressed probe-based data storage devices, which are considered as possible solution for the next generation of high density and fast operation devices. Additionally, ferroelectric materials are considered as good candidates for gate dielectric materials in field effect transistor applications, which is due to their high permittivity.

Writing data in a non-volatile ferroelectric memory device is usually achieved by applying an electric field, which exceeds the coercive field E_{c} of the ferroelectric material in the direction normal to the thin ferroelectric film, which is itself sandwiched between two layers of electrodes. Under the effects of the electric field, ferroelectric domains that are oriented favorably with respect to the applied field direction nucleate and subsequently grow at the expense of other domains. This process continues until the domain growth arrives at completion and a complete reorientation has occurred. A single bit of information, which is a polarization state determined by the orientation of the local electric dipole moment of the ferroelectric material, can then be stored in the ferroelectric memory cell. Reading is achieved by detecting the polarization state by one or more means well known to the person skilled in the art.

The ferroelectric thin film in a ferroelectric memory device or gate-dielectric layer of a field effect transistor, may be made of an inorganic material such as lead zirconate titanate (PZT), barium titanate (BaTiO₃) and similar perovskite-like ceramics. However, organic materials, e.g. polymer materials with polar group such as poly(vinylidene fluoride) (PVDF) or its copolymer with trifluoroethylene (typically abbreviated P(VDF-TrFE)), odd numbered nylons or polyvinylidene cyanide p(VCN), provide considerable advantages as compared to their inorganic counterparts, due to their solution processing ability, lower processing temperature and lower cost. A FeRAM device using P(VDF-TrFE) can exhibit microsecond initial read speeds coupled with write speeds comparable to Flash memories. Moreover, ferroelectric polymer layers can be stacked to improve memory cell density. Furthermore, P(VDF-TrFE) copolymers are wide bandgap insulators, while their inorganic counterparts are usually semiconductive due to imperfections created during crystal growth.

Another important requirement for a ferroelectric polymer memory device is a fast write and read speed. Below the Curie temperature (i.e. the temperature at which the behavior of the material changes from ferroelectric to paraelectric), the backbone of a ferroelectric polymer typically arranges in an all-trans conformation. The global dipole moments of each ferroelectric domain, which is perpendicular to the backbones of the polymer chains, are parallel to each other. The ferroelectric domains are separated from each other by domain walls and organize into grains. In such a situation, the process of domain switching, which is required to store data, is mainly determined by the nucleation of small reversed domains and the subsequent domain growth. This process results in an elongated switching time under a given voltage due to the pinning of domain walls by structural defects.

Additionally, the signal-to-noise ratio of ferroelectric polymer devices should be as high as possible. The signal-to-noise ratio under a given operation voltage mainly depends on the polarization of the ferroelectric material, which is mainly determined by dipole moments, their orientation and their surface area density. In a conventional method of manufacturing ferroelectric polymer devices, a ferroelectric polymer thin film is polarized by applying an external electric field to two parallel electrodes above the Curie temperature, in order to align the dipoles in the direction normal to the thin film. However, the process typically results in the degradation of the interface between the electrode and polymer thin film, and thus to the deterioration of the ferroelectric properties.

An important requirement for ferroelectric polymer memory devices is that the operation voltage should be as low as possible. The operation voltage depends for instance on the thickness of the ferroelectric polymer medium used in the memory device. For instance, due to the relative high coercive field E_{c} of 50 MV/m of P(VDF-TrFE) copolymers, sub-100 nm thin films are required in order to attain an operation voltage lower than 10 Volt. However, investigations of the thickness dependence of the polarization behavior show a decline in the ferroelectric switching performance (for example, an increase of coercive field, a lower remnant polarization, and/or a longer switching time), when the film thickness is reduced to below 100 nm. The decline in performance has been mainly attributed to the reduction of crystallinity and/or crystallite size. Attempts to avoid the deterioration of ferroelectric performance below 100 nm film thickness have been proposed before: R. C. G. Naber, P. W. M. Blom, A. W. Marsman, D. M. de Leeuw, Applied Physics Letters 85, 2023 (2004), proposed using a conducting polymer as bottom electrode, in order to improve the ferroelectric properties of sub-100-nm-thick spin cast P(VDF-TrFE) films. A coercive voltage of 5.2V was achieved for a 65 nm thick film, corresponding to a coercive field of about 80 MV/m, still higher than the one of bulk samples (ca 50 MV/m). Likewise, Takeo Furukawa, Takashi Nakajima, Yoshiyuki Takahashi, IEEE Trans. Dielectrics Electrical Insulation 13, 1120 (2006), indicate that coercive fields in the range of 50 MV/m can be obtained for annealed spin cast 80 nm-thick P(VDF-TrFE) films when Al electrodes are replaced by Au electrodes. Such values of coercive field correspond to effective operating voltages of 10V for 100 nm-thin films. However, lower voltages, in the range of 2 V are of interest for practical applications, including compatibility with CMOS technology. There is therefore still a need in the art for ferroelectric polymer memory devices able to operate at a low voltage.

Zhang et al (Lei Zhang, Stephen Ducharme, Jiangyu Li, Applied Physics Letters 91, 172906 (2007)) disclose 50 μm thick microimprinted P(VDF-TrFE) copolymer films. A 10 V DC voltage is applied on a 1 μm² area of the film to obtain a locally poled area. Such a high voltage is usually not available in microelectronic devices. Also disclosed in Zhang et al is a 3 μm thick microimprinted P(VDF-TrFE) copolymer film together with its ferroelectric hysteresis curve (FIG. 2(a) of Zhang et al). From this hysteresis curve, the coercive voltage Vc can be evaluated to be around 375 V, which for a thickness of 3 μm gives a Coercive field of c.a. 125 MV/m. With such a high coercive field, 10 V would not be enough to switch the polarity of a 100 nm film.

Finally, preferred orientation of the axes of the crystal of the ferroelectric polymer material is also an important feature able to increase performance. For instance, it is usually considered that ferroelectric polymers switch the orientation of their permanent dipole moments by a molecular process involving the rotation of segments of chains around the chain axis, usually denoted as c-axis. Optimum coupling between the switching field and the dipole moment thus require the c-axis to be perpendicular to the applied field. For this film geometry, this corresponds to polymer crystals having their c-axis in plane. Unfortunately, none of the previously published methods or procedures is able to obtain this control over the orientation of polymer crystals and thus the c-axis. There is therefore a need in the art for a method permitting the manufacture of a ferroelectric memory device comprising polymer ferroelectric components having their molecular dipole moment perpendicular to the surface on which they are deposited. Furthermore, the methods at present used for improving the ferroelectric properties of polymer memory devices are very tedious and labour-intensive.

### SUMMARY OF THE INVENTION

It is an object of the present invention to provide methods to manufacture ferroelectric organic memory devices with good ferroelectric switching performances.

It is an advantage of embodiments of the present invention that a low operation voltage in ferroelectric organic memory devices can be achieved. It is also an advantage of embodiments of the present invention that fast switching speed in ferroelectric organic memory devices can be achieved. It is also an advantage of embodiments of the present invention that a high signal-to-noise ratio in the data reading process of ferroelectric organic memory devices can be achieved. It is also an advantage of embodiments of the present invention that high storage density in ferroelectric organic memory devices can be achieved.

It is an advantage of embodiments of the present invention that a ferroelectric polymer material can be oriented in such a way as to align in the plane of the substrate the axis about which the dipolar moment rotates (i.e. the axis oriented in the same direction as the polymer chains also referred as the c-axis), without needing to apply an external electric field to obtain said orientation and therefore without degrading the interface between the electrode and the ferroelectric polymer material. This orientation results in optimal coupling between dipole moment and a vertical electric field (i.e. a field perpendicular to the substrate), and allows for easier rotation of the dipole moment.

Another advantage of embodiments of the present invention is that a method is provided which is capable of orienting specifically the ferroelectric crystals in specific direction, thereby allowing for improved coupling with the electric field.

Another advantage of embodiments of the present invention is that devices such as, but not limited to memories, can be manufactured having improved function and performance provided by the specific orientation of a ferroelectric polymer material. The polymer material may be a ferroelectric polymer such PVDF, P(VDF-TrFE), odd nylon, P(VCN), or any other crystalline or liquid crystalline ferroelectric polymer; the orientation being attained by methods according to embodiments of the present invention.

In embodiments of the present invention, the orienting and nanostructuring may be obtained by a simple embossing and annealing step in the paraelectric phase of the ferroelectric organic (e.g. polymer) materials. Patterned sub-100 nm ferroelectric polymer nanostructures have been fabricated in embodiments of the present invention.

Each element (i.e. nanostructure) of the patterned ferroelectric polymer may have a fine grain structure or may even be a single crystal, in which the dipole moment is parallel or anti-parallel to the normal of the underlying substrate. In the case of P(VDF-TrFE), the coercive field E_{c} of the nanostructures may be decreased from 50 MV/m for a non-patterned film to 10 MV/m or lower (and the remnant polarization may be increased) for a patterned film according to embodiments of the present invention. In embodiments of the present invention, an operation voltage of less than 2.0 Volt in absolute value may be thus high enough to write or/and read in 100 nm thick nanostructures of the ferroelectric organic memory devices according to embodiments of the present invention. In embodiments of the present invention, a switching speed less than one microsecond and a higher signal-to-noise ratio are also obtainable.

The above objective is accomplished by a method and device according to the present invention.

In a first aspect, the present invention relates to a ferroelectric organic memory device comprising:
a substrate,
a first electrode, and
a set of one or more ferroelectric polymer elements, each of said one or more ferroelectric polymer elements having at least two dimensions measuring from 5 to 1000 nm and wherein said elements either:
   are unattached to each other (in other words, are non-contiguous, see FIGS. 15B and D), or
   are attached to each other by a ferroelectric polymer material having a average thickness T representing maximum 20% of the dimension V of the one or more ferroelectric polymer elements (204, 304), wherein V is the dimension perpendicular to the substrate surface (see FIGS. 15A and C).

Expressed differently, this first aspect of the present invention relates to a ferroelectric organic memory device comprising:
a substrate,
a first electrode, and
a set of one or more ferroelectric polymer elements, each of said one or more ferroelectric polymer elements having at least two dimensions measuring from 5 to 1000 nm and wherein said elements either:
   form a discontinuous ferroelectric layer (see FIG. 15B or D), or
      form part of a continuous ferroelectric layer wherein the layer portion assuring the continuity between said one or more ferroelectric polymer elements has an average thickness T representing maximum 20% of the average maximum extension (i.e. dimension) V of said one or more elements measured perpendicularly to the substrate surface (see FIGS. 15A and C).

Expressed differently, this first aspect of the present invention relates to a ferroelectric organic memory device comprising:
a non-ferroelectric substrate,
a first electrode and
a set of one or more ferroelectric polymer elements, wherein said one or more ferroelectric polymer elements have at least two dimensions measuring in average from 5 to 1000 nm, wherein said set of one or more ferroelectric polymer elements either:
   form a discontinuous ferroelectric layer (see FIGS. 15B and D), or
   form part of a continuous ferroelectric layer comprising said set of one or more ferroelectric elements and a portion assuring a layer continuity between said one or more ferroelectric polymer elements wherein said portion has an average thickness T representing maximally 20% of the average height (see FIG. 15A) or depth (see FIG. 15C) V of said one or more ferroelectric polymer elements.

This first aspect is advantageous since such devices can be driven at a very low voltage, even for a relatively large thickness.

As an optional feature of this first aspect, said one or more elements may form a pattern of fixed or variable period.

As another additional feature of this first aspect, the average orientation of the chain axis of the elements of the set may be substantially parallel to the substrate surface. This is advantageous because it permits to more easily orient, perpendicularly to the substrate surface, the average dipolar moment of the elements.

As another additional feature of this first aspect, the ferroelectric hysteresis loop of said device may be characterised by a coercive field of 20 MV/m or less, preferably 15 MV/m or less, most preferably 10 MV/m or less. This is advantageous as it permits to switch the polarity of an element at a low voltage.

As another additional feature of this first aspect, the ratio of the A₁ absorbance band (e.g. at ˜1400 cm⁻¹) to the B₁ absorbance band (e.g. at ˜1288 cm⁻¹) in an FT-IR reflection-absorption spectrum of said set may be larger than 2, preferably larger than 5 more preferably larger than 7. This is advantageous because it indicates that the average relative orientation of the chain axis of the elements of the set is parallel to the substrate surface. The location of the absorbance bands has some variability depending on the method used to probe it (e.g., reflection or transmission; or parameters of acquisition.)

As an optional feature, each of said one or more ferroelectric polymer elements may have at least two dimensions measuring from 5 to 500 nm. It is advantageous, because it is in this size range that the vertical orientation of the dipoles (i.e. perpendicular to the substrate surface) is more easily achieved.

As another optional feature, one of said at least two dimensions may be the dimension perpendicular to the substrate surface (e.g. the depth (V in FIGS. 15C and D) or height (V in FIGS. 15A and B) of the elements or when this depth or height is the smallest of the three dimensions of the elements, which is often but not always the case, the thickness of the element).

As an optional feature, the one or more ferroelectric polymer elements may comprise a semi-crystalline or liquid crystalline polymer.

As another optional feature, when the ferroelectric polymer comprises a semi-crystalline polymer, said semi-crystalline polymer may comprise a copolymer of vinylidene fluoride and trifluoroethylene. This is advantageous because this ferroelectric polymer is particularly efficient.

As another optional feature, when the ferroelectric polymer comprises a copolymer of vinylidene fluoride and trifluoroethylene said copolymer may comprise from 20 to 40 mol % of trifluoroethylene. This is within this range that the best ferroelectric properties are achieved.

As another additional feature, the dipolar moment of said one or more ferroelectric polymer elements may be reversible in 1 μs or less.

As another optional feature, all of said one or more ferroelectric polymer elements have substantially the same dimensions. This is advantageous as it permits a well-defined and uniform operation of all elements in a given memory device.

As another optional feature, said one or more ferroelectric polymer elements may have walls perpendicular to the substrate surface.

As another optional feature, each of said one or more ferroelectric polymer elements may comprise a single crystal, preferably comprising no or only a few defects. When each element is a single crystal, a well-defined and uniform operation is enabled from element to element and the switching time is decreased.

As another optional feature, the first electrode may form a continuous and homogeneous layer on said substrate. This is an easy way to provide the electrode.

As another optional feature, the device may further comprise a dielectric layer. This is advantageous because such a dielectric layer can be selected in such a way as to be easier to structure than the substrate itself.

As another additional feature, when a dielectric layer is present, it may comprise holes having at least two dimensions measuring from 5 to 1000 nm. This is advantageous as those holes can serve to direct the orientation of the ferroelectric crystals during their formation.

As another optional feature, when the first electrode forms a continuous and homogeneous layer on said substrate, and when a dielectric layer comprising holes is present, said holes may extend through the whole thickness of said dielectric layer. This is advantageous as it allows a contact between the first electrode and the ferroelectric elements.

As another optional feature, the device may further comprise one or more transistors. This is advantageous as they can be used to switch individually each ferroelectric elements.

In an embodiment of the first aspect, the present invention relates to a ferroelectric polymer memory device where preferential orientation and patterning of the polymer ferroelectric medium is achieved by applying a mold bearing nano-features (5-1000 nm, preferably 10-1000 nm in at least one lateral direction, and 5-1000 nm in the vertical direction) into a ferroelectric polymer film, or by confining the film in nano-cavities present in the substrate or the optional ILD layer (from 5 to 1000 nm, preferably 10 to 1000 nm size in at least one lateral direction, and from 5 to 1000 nm in the vertical direction), and annealing above the Curie point and below the melting temperature, for times of at least 1 minute, such as e.g. between 1 and 120 minutes, preferably between 5 and 60 minutes, more preferably between 20 and 40 minutes, most preferably between 25 and 35 minutes (for instance 30 minutes).

As an optional feature of the first aspect of the present invention, each of said elements comprises (or consists of) one or more crystal domains in which the axis about which the dipole moment can rotate, which is the chain axis for most polymers (and in particular for P(VDF-TrFE)), is in the plane of the substrate.

As another optional feature of the first aspect of the present invention, each of said one or more crystal domains contain only few crystal defects or no defects at all. This can be concluded from the observation of an AFM image as shown in FIG. 13 and from the sharpness of the hysteresis loop as shown in FIG. 6.

In a second aspect of the present invention, the present invention relates to an array of devices according to the first aspect of the present invention.

In a third aspect, the present invention relates to methods for manufacturing a ferroelectric organic memory device, said method comprising the steps of:
Providing a non-ferroelectric substrate,
Optionally applying a conductive material on said non-ferroelectric substrate,
Optionally forming a dielectric layer onto said non-ferroelectric substrate or onto said conductive material and performing (i.e. making) holes into said dielectric layer, said holes having at least two dimensions comprised between 5 and 1000 nm,
If no conducting material has been applied yet, forming a layer of conductive material into said holes or onto said non-ferroelectric substrate, and
forming a set of one or more ferroelectric polymer elements having at least two dimensions measuring from 5 to 1000 nm onto said conductive material wherein said set of one or more ferroelectric polymer elements either:
form a discontinuous ferroelectric layer (see FIG. 15B or D), or
form part of a continuous ferroelectric layer comprising said set of one or more ferroelectric elements and a portion assuring a layer continuity between said one or more ferroelectric polymer elements wherein said portion has an average thickness T representing maximally 20% of the average height (see FIG. 15A) or depth (see FIG. 15C) (or average maximum extension (i.e. dimension) measured perpendicularly to the substrate surface) V of said one or more ferroelectric polymer elements.

In an embodiment of the third aspect of the present invention, the step of forming a set of one or more ferroelectric polymer elements may comprise the steps of:
applying a ferroelectric polymer layer onto at least part of said conductive material or forming a ferroelectric polymer thin film on the dielectric layer comprising said holes, and
solvent annealing said polymer layer before or during said forming of said set.

After or during the solvent annealing step, said step of forming a set of one or more ferroelectric polymer elements may comprise the steps of, where a ferroelectric polymer layer has been applied onto at least part of said conductive material,
optionally heating up a mold comprising elements having at least two dimensions measuring from 5 to 1000 nm and/or said ferroelectric polymer layer (209) to a temperature higher than room temperature but lower than the melting temperature of said ferroelectric polymer layer,
pressing said mold into said ferroelectric polymer layer,
setting the temperature of said mold and/or said ferroelectric polymer material to a temperature lower than the Curie temperature of said ferroelectric material, and
removing said mold from said ferroelectric polymer material, thereby providing a device comprising said set of one or more ferroelectric elements,
   or where a ferroelectric polymer thin film (808) has been formed on the dielectric layer (103, 803) comprising said holes:
pressing a flat plate (303) onto the ferroelectric polymer thin film (808), wherein the temperature of the plate and/or the film is at or above room temperature but below the melting point of the ferroelectric polymer;
setting the temperature of the plate (303) and ferroelectric polymer material below the Curie temperature; and
removing the plate (303) from the ferroelectric polymer material to provide said set.

As an optional feature, the step of forming a set may comprise the step of applying a ferroelectric polymer material into said holes.

Alternatively, said step of forming a set may comprise the steps of:
Applying a ferroelectric polymer layer onto at least part of said conductive material,
Bringing a mold comprising elements having at least two dimensions measuring from 5 to 1000 nm and/or said ferroelectric polymer layer to a temperature higher than the Curie temperature of said ferroelectric polymer layer but lower than the melting temperature of said ferroelectric polymer layer,
Pressing said mold into said ferroelectric polymer layer,
Bringing the temperature of said mold and/or said ferroelectric polymer material to a temperature lower than the Curie temperature of said ferroelectric material, and
Removing said mold from said ferroelectric polymer material, thereby providing a device comprising said set.

In an embodiment of this third aspect, the present invention relates to a method of manufacturing patterned ferroelectric organic memory media, comprising:
forming a lower electrode (e.g. a conductive layer) on a substrate;
forming a ferroelectric polymer thin film on the electrode;
pressing a mold comprising nanocavities into the ferroelectric polymer thin film, wherein said mold and/or said film are at a temperature higher than the Curie temperature of the ferroelectric polymer but lower than the melting point of the ferroelectric polymer, wherein said nanocavities have at least two dimension from 5 to 1000 nm;
cooling the mold and ferroelectric polymer material below the Curie temperature of the ferroelectric polymer; and
removing the mold from the ferroelectric polymer material to provide a plurality of nanostructures, wherein said nanostructures form a discontinuous layer (see FIG. 15B) or a continuous layer wherein the layer portion assuring the continuity between the nanostructures has an average thickness T representing maximum 20% of the average maximum extension (i.e. dimension) V of said nanostructures measured perpendicularly to the substrate surface (see FIG. 15A).

As an additional feature of this embodiment of the third aspect of the present invention, the lower electrode may be homogenously deposited on a substrate.

As an optional feature of this embodiment of the third aspect of the present invention, the ferroelectric polymer thin film may be deposited on the electrode by spin cast techniques.

In yet another optional feature of this embodiment of the third aspect of the present invention, the ferroelectric polymer material may comprise one of a copolymer of vinylidene fluoride (VDF) and trifluoroethylene (TrFE).

As another optional feature of this embodiment of the third aspect of the present invention, the ferroelectric polymer thin film may be embossed with a hard mold at a pressure comprised between 10 bar and 70 bar.

As another optional feature of this embodiment of the third aspect of the present invention, the mold may comprise silicon, silicon oxide, quartz, metal, or a hard polymer, coated with an antisticking agent such as a perfluorodecylsilane, and manufactured with lithography and etching. In embodiments, the mold may be a stamp.

As another optional feature of the third aspect of the present invention, the mold may comprise cavities or protrusions of lateral dimension below 1000 nm in at least one direction, and of depth ranging from 5 to 1000 nm.

In another embodiment of this third aspect, the present invention relates to a method of manufacturing patterned ferroelectric organic memory media, comprising:
forming a lower electrode on a substrate;
forming an ILD layer over the electrode;
forming nanocavities in the ILD layer;
forming a ferroelectric polymer thin film on the ILD layer;
pressing a flat plate (preferably a hard flat plate) onto the ferroelectric polymer thin film, wherein the temperature of the plate and/or the film is above the Curie temperature of the ferroelectric polymer but below the melting point of the ferroelectric polymer;
cooling the plate and ferroelectric polymer material below the Curie temperature; and
removing the plate from the ferroelectric polymer material to provide a plurality of nanostructures, wherein said nanostructures form a discontinuous layer (see FIG. 15D) or a continuous layer (see FIG. 15C) wherein the layer portion assuring the continuity between the nanostructures has an average thickness T representing maximum 20% of the average maximum extension (i.e. dimension) V of said nanostructures measured perpendicularly to the substrate surface.

As an optional feature of this embodiment of the third aspect, the lower electrode may be homogenously deposited onto a substrate.

As another optional feature of this embodiment of the third aspect, the ILD layer may be established by chemical vapor deposition, sputter deposition, plasma vapor deposition, or spin casting techniques.

As another optional feature of this embodiment of the third aspect, the ILD layer may comprise silicon oxide, silicon nitride, silicon carbide, aluminum oxide or polymers.

As another optional feature of this embodiment of the third aspect, the ILD layer may be patterned with nanocavities (which go completely or partially through the ILD layer) by lithography and etching.

As another optional feature of this embodiment of the third aspect, the ILD layer may comprise cavities or protrusions of lateral dimension below 1000 nm in at least one direction (for instance between 5 and 1000 nm). As another optional feature of this embodiment of the third aspect of the present invention, the ILD layer may comprise cavities or protrusions having a depth ranging from 5 to 1000 nm or 10 to 1000 nm, preferably 5 to 500 nm or 10 to 500 nm, more preferably 5 to 200 nm or 10 to 200 nm, most preferably 5 to 100 nm or 10 to 100 nm.

As another optional feature of this embodiment of the third aspect, the ferroelectric polymer thin film may be deposited onto the surface of the ILD layer and bottom of the nanocavities by spin cast techniques.

As another optional feature of this embodiment of the third aspect, the ferroelectric polymer material may comprise one of a copolymer of vinylidene fluoride (VDF) and trifluoroethylene (TrFE).

As another optional feature of this embodiment of the third aspect, the ferroelectric polymer thin film may be pressed in the nanocavities of the ILD layer with a hard flat plate at a pressure comprised between 10 bar and 70 bar.

As another optional feature of this embodiment of the third aspect, after the applying the flat plate, the eventually remaining layer portion connecting the ferroelectric elements may be removed, e.g. by a polishing technique.

As another optional feature of this embodiment of the third aspect, the hard flat plate may comprise silicon, silicon oxide, quartz, metal, or a hard polymer, coated or not with a release agent such as perfluorodecylsilane.

In another embodiment of the third aspect, the present invention relates to a method of manufacturing patterned ferroelectric organic memory media, comprising:
forming an ILD layer on a substrate;
forming nanoholes (e.g. nanotrenches) in the ILD layer wherein said nanoholes have at least two dimensions ranging from 5 to 1000 nm or 10 to 1000 nm, preferably 5 to 500 nm or 10 to 500 nm, more preferably 5 to 200 nm or 10 to 200 nm, most preferably 5 to 100 nm or 10 to 100 nm;
forming a lower electrode in the nanoholes defined in the ILD layer;
depositing a ferroelectric polymer thin film on the ILD layer and in the nanoholes;
pressing a hard flat plate onto the ferroelectric polymer thin film, wherein the temperature of the plate and/or the ferroelectric polymer film is higher than the Curie temperature but lower than the melting temperature of the ferroelectric polymer film;
cooling the plate and ferroelectric polymer material; and
removing the plate from the ferroelectric polymer material to provide a plurality of nanostructures, wherein said nanostructures form a discontinuous layer (see FIG. 15D) or a continuous layer wherein the layer portion assuring the continuity between the nanostructures has an average thickness T representing maximum 20% of the average maximum extension (i.e. dimension) V of said nanostructures measured perpendicularly to the substrate surface (see FIG. 15C).

As an optional feature of this embodiment of the third aspect of the present invention, the ILD layer may be established by chemical vapor deposition, sputter deposition, plasma vapor deposition, electrografting or spin casting techniques.

As another optional feature of this embodiment of the third aspect of the present invention, the ILD layer may comprise silicon oxide, silicon nitride, silicon carbide, aluminum oxide, or polymers.

As another optional feature of this embodiment of the third aspect of the present invention, the ILD layer may be patterned with nanoholes (e.g. nanotrenches or nanocavities) by lithography and etching. In embodiments, the nanoholes can go completely or partially through the ILD layer

As another optional feature of this embodiment of the third aspect of the present invention, the ILD layer may comprise holes (e.g. trenches) or protrusions of lateral dimension below 1000 nm in at least one direction, e.g. from 5 to 1000 nm or 10 to 1000 nm, preferably 5 to 500 nm or 10 to 500 nm, more preferably 5 to 200 nm or 10 to 200 nm, most preferably 5 to 100 nm or 10 to 100 nm, and of depth ranging from 5 to 1000 nm or 10 to 1000 nm, preferably 5 to 500 nm or 10 to 500 nm, more preferably 5 to 200 nm or 10 to 200 nm, most preferably 5 to 100 nm or 10 to 100 nm.

As another optional feature of this embodiment of the third aspect of the present invention, the lower electrode may be deposited onto the ILD layer and in the bottom of nanotrenches or nanoholes.

As another optional feature of this embodiment of the third aspect of the present invention, the conducting material deposited onto the ILD layer may be polished away by chemical polishing process (CMP).

As another optional feature of this embodiment of the third aspect of the present invention, a ferroelectric polymer thin film may be deposited onto the surface of the ILD layer and at the bottom of the nanotrenches or nanoholes by spin cast techniques.

As another optional feature of this embodiment of the third aspect of the present invention, the ferroelectric polymer material may comprise one of a copolymer of vinylidene fluoride (VDF) and trifluoroethylene (TrFE).

As another optional feature of this embodiment of the third aspect of the present invention, the ferroelectric polymer thin film may be pressed with a flat plate, preferably a hard flat plate at a pressure from 10 bar to 70 bar.

As another optional feature of this embodiment of the third aspect of the present invention, the hard flat plate may comprise silicon, silicon oxide, quartz, metal, or polymer coated or not with a suitable antisticking agent such as perfluorodecylsilane.

In an embodiment of the third aspect, the present invention relates to a method of improving ferroelectric performances in ferroelectric organic memory media, comprising:
embossing a ferroelectric polymer thin film on a substrate into a plurality of nanostructures in the paraelectric phase of the ferroelectric material, i.e. above the Curie temperature but below the melting temperature;
annealing the ferroelectric polymer nanostructures in the paraelectric phase while maintaining a high pressure between 10 bar and 70 bar; and
cooling the ferroelectric polymer nanostructures below the Curie temperature while maintaining said pressure within said range.

For P(VDF-TrFE), the Curie temperature lies between approximately 65 and 175 degree Celsius, depending on the composition of the copolymer. This polymer material changes from the ferroelectric phase to the paraelectric phase in this temperature range.

In any embodiments of the third aspect of the present invention, the presence of solvent in the ferroelectric material may have for effect to decrease the Curie temperature and/or the melting temperature. When a combination of solvent annealing and thermal annealing is used, such a decrease in the transition temperatures is preferably taken into account (e.g. so as not to exceed the melting temperature of the solvent-containing ferroelectric material during the formation of the set of one or more ferroelectric polymer elements).

Although the annealing time is not a critical aspect of the third aspect of the present invention, annealing is preferably performed for at least 1 minute and can be prolonged for a few hours or more. In an embodiment of this aspect of the present invention, the annealing is performed between 1 and 120 minutes, preferably between 5 and 60 minutes, more preferably between 20 and 40 minutes, most preferably between 25 and 35 minutes (for instance 30 minutes) before pressing the mold or the plate.

In another embodiment of this aspect of the present invention the annealing is performed after pressing the mold or plate while maintaining a pressure which may be higher, lower than or close to the pressure used to press the mold or plate, for between 1 and 120 minutes, preferably between 5 and 60 minutes, more preferably between 20 and 40 minutes, most preferably between 25 and 35 minutes (for instance 30 minutes). In an embodiment of this aspect of the present invention, the cooling is performed while maintaining a pressure which may be higher, lower than or close to the pressure used to press the mold or plate.

In a fourth aspect, the present invention relates to the use of a ferroelectric organic memory device at a driving field of 20 MV/m or less, preferably 15 MV/m or less, more preferably 10 MV/m or less, said device comprising:
a substrate, and
a set of one or more ferroelectric polymer elements, each of said one or more ferroelectric polymer elements having at least two dimensions measuring from 5 to 1000 nm or 10 to 1000 nm, preferably 5 to 500 nm or 10 to 500 nm, more preferably 5 to 200 nm or 10 to 200 nm, most preferably 5 to 100 nm or 10 to 100 nm and wherein said elements either:
form a discontinuous ferroelectric layer, or
form part of a continuous ferroelectric layer wherein the layer portion assuring the continuity between said one or more ferroelectric polymer elements has an average thickness T representing maximum 20% of the average maximum extension (i.e. dimension) V of said one or more elements measured perpendicularly to the substrate surface.

In a further aspect, the present invention relates to a ferroelectric device obtainable by any of the manufacturing methods listed in any of the embodiments of the third aspect above. For instance, the present invention relates in some embodiments to a ferroelectric device obtainable by patterning or by embossing a film of said polymer material by a mold bearing nanofeatures, or by confining the film into nanocavities, and annealing above the Curie point and below the melting temperature for at least 1 minute. The lateral extension (i.e. dimension) of the nanofeatures of the mold or of the nanocavities (e.g. in the ILD layer), in at least one lateral direction, ranges from 5 to 1000 nm or 10 to 1000 nm, preferably 5 to 500 nm or 10 to 500 nm, more preferably 5 to 200 nm or 10 to 200 nm, most preferably 5 to 100 nm or 10 to 100 nm. The vertical extension (i.e. dimension) of the nanofeatures of the mold or of the nanocavities (e.g. in the ILD layer), ranges from 5 to 1000 nm or 10 to 1000 nm, preferably 5 to 500 nm or 10 to 500 nm, more preferably 5 to 200 nm or 10 to 200 nm, most preferably 5 to 100 nm or 10 to 100 nm.

Particular and preferred aspects of the invention are set out in the accompanying independent and dependent claims. Features from the dependent claims may be combined with features of the independent claims and with features of other dependent claims as appropriate and not merely as explicitly set out in the claims.

Although there has been constant improvement, change and evolution of devices in this field, the present concepts are believed to represent substantial new and novel improvements, including departures from prior practices, resulting in the provision of more efficient, stable and reliable devices of this nature.

The teachings of the present invention permit the design of improved ferroelectric organic memory devices.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF DRAWINGS

The above and other features and advantages of the present invention will become more apparent by describing in detail exemplary embodiments thereof with reference to the attached drawing in which:

FIG. 1a through 1c are cross-sectional views of ferroelectric organic memory devices according to embodiments of the present invention.

FIGS. 2a through 2d illustrate a method of manufacturing patterned ferroelectric polymer nanostructures and controlling the orientation of polymer chains and dipole moments in the nanostructures according to another embodiment of the present invention.

FIGS. 3a through 3d illustrate another method of manufacturing patterned ferroelectric polymer nanostructures and controlling the orientation of polymer chains and dipole moments in the nanostructures according to another embodiment of the present invention.

FIG. 4a shows an atomic force microscopy (AFM) picture of a continuous P(VDF-TrFE) thin film prepared according to the prior art. FIGS. 4b and 4c present two examples of P(VDF-TrFE) thin films patterned with nanostructures with preferred orientation of polymer chains and dipole moments fabricated according to embodiments of the present invention.

FIG. 5a shows an electron diffraction image (left) and a transmission electron microscopy (TEM) (right) of a continuous ferroelectric polymer thin film according to the prior art. FIG. 5b shows an electron diffraction image (left) and a TEM picture (right) of patterned ferroelectric nanostructures according to an embodiment of the present invention, where preferential crystal alignment is demonstrated.

FIG. 6 is a graph illustrating the response characteristics of patterned ferroelectric polymer nanostructures according to an embodiment of the present invention (triangles) and of continuous ferroelectric polymer thin films according to the prior art (squares).

FIGS. 7a and 7b are cross-sectional views of a probe-based ferroelectric organic memory device using patterned ferroelectric polymer nanostructures according to an embodiment of the present invention.

FIG. 8a through 8d illustrates a method of manufacturing an electrically addressable ferroelectric organic memory device using patterned ferroelectric polymer nanostructures according to an embodiment of the present invention.

FIG. 9 shows the unit cell of the β phase of P(VDF-TrFE) with its three axes a, b and c.

FIG. 10 is a three-dimensional representation of a P(VDF-TrFE) crystal in its β phase.

FIG. 11 (top, left) shows the transmission electron microscopy image of a continuous 100 nm film of P(VDF-TrFE) according to the prior art. FIG. 11 (top, right) shows the electron diffraction pattern of this film according to the prior art. FIG. 11 (bottom, left) shows the transmission electron microscopy image of nano-patterned film (initial thickness: 50 nm, height of pattern after embossing: 100 nm) according to an embodiment of the present invention. FIG. 11 (bottom, right) shows the electron diffraction pattern of this film according to the present invention.

FIG. 12 shows the Fourier transform infrared reflection-absorption spectroscopy at normal incidence of a an annealed 130 nm thick continuous film of P(VDF-TrFE) according to the prior art (curve B) and of an 100 nm thick nano-embossed film according to an embodiment of the present invention (curve A).

FIG. 13 shows an Atomic Force Microscopy phase image of a nano-embossed film (initial thickness=50 nm) of P(VDF-TrFE) according to an embodiment of the present invention.

FIG. 14 shows an AFM phase image of a 50 nm thick film of P(VDF-TrFE) according to the prior art.

FIG. 15 shows four examples of devices according to the present invention.

In the different figures, the same reference signs refer to the same or analogous elements.

### DESCRIPTION OF ILLUSTRATION EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Similarly, it is to be noticed that the term “coupled”, also used in the claims, should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

The following terms are provided solely to aid in the understanding of the invention.

The term “article” may include any underlying material or materials that may be used, or upon which a device or a circuit may be formed or embedded.

The terms “hole” and “cavity” are used as synonyms and are general terms encompassing any depression of any shape made in a substrate or dielectric layer. In the case of a dielectric layer (e.g. an ILD layer), those depression can go partially or completely through the dielectric layer. In the case of holes directly made in a substrate, the hole is a depression which goes partially through the substrate. As used herein and unless provided otherwise, the term “trench” relates to an elongated hole.

When used herein and unless provided otherwise, the term “dimension” must be understood as any of the thickness, the length and the width of an element or feature.

The number of dimensions that an element has will always be considered as being exactly three: its lengths, its width and its thickness. The “thickness” of an element or feature must be understood as the smallest of these three dimensions (length, width, and thickness). The “length” of an element or feature must be understood as the largest of the three dimensions and the width must be understood as the remaining dimension. In some embodiments, an element may have two or all of its three dimensions the same. For instance, a circular element will always have at least two dimensions the same (length and width, or width and thickness). An element having length and thickness the same, has necessarily also its width the same as its length and thickness. For an element having any shape (e.g. an irregular shape), the length, width and thickness of the element will be the same as the length width and thickness of the smallest rectangular parallelepiped which can comprise entirely said shape, wherein one face of said rectangular parallelepiped is comprised in the substrate's surface.

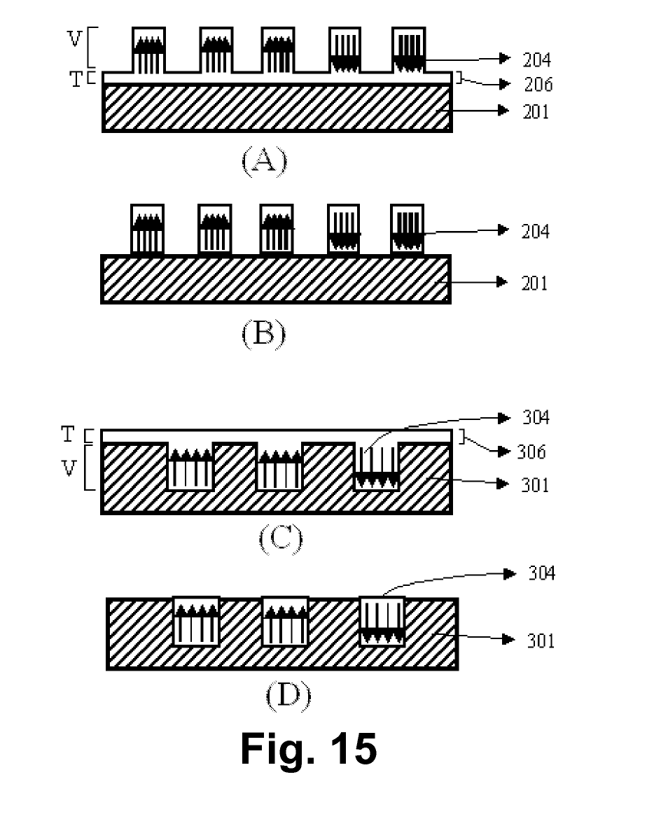

In general, the dimension of the ferroelectric polymer elements perpendicular to the surface of the non-ferroelectric substrate (in the case of unattached ferroelectric polymer elements, see FIG. 15B or 15D) or perpendicular to the layer portion assuring the continuity between the ferroelectric polymer elements (in the case where the ferroelectric polymer elements form a continuous ferrroelectric layer, see FIG. 15A or 15C) can be referred to as height (FIGS. 15A and B) or depth (FIGS. 15C and D) depending upon the configuration, but both represent a single dimension V perpendicular to the surface of the non-ferroelectric substrate or perpendicular to the layer portion assuring the continuity between the ferroelectric polymer elements. In the case where the ferroelectric polymer elements form a continuous ferroelectric layer, the thickness T of the layer portion assuring the continuity between said one or more ferroelectric elements is not comprised in V (see FIGS. 15A and C).

The term “polymer” must be understood as a molecule containing 20 or more monomers. A molecule containing less than 20 monomers will be considered an “oligomer”. This is in agreement with the definition given in Michael Rubinstein & Ralph H. Colby, “Polymer Physics”, Oxford University Press: Oxford (2003)—p. 5.

“Solvent annealing” is here understood to mean the subjecting of a material to the influence of a solvent for a period of time with the goal of a desirable change in the material. For instance, “solvent annealing” may refer to the exposing of the ferroelectric polymer layer to a vapor derived from a solvent. As used herein and unless provided otherwise, the word “solvent” when used alone is understood to refer to the liquid phase of the solvent while “vapor” is understood to refer to the gas phase of the solvent but the wording solvent annealing refers to the use of either or both solvent and vapor.

The invention will now be described by a detailed description of several embodiments of the invention. It is clear that other embodiments of the invention can be configured according to the knowledge of persons skilled in the art without departing from the true spirit or technical teaching of the invention, the invention being limited only by the terms of the appended claims.

In a first aspect, the present invention relates to ferroelectric organic memory devices. Generally speaking, ferroelectric organic memory devices according to this first aspect of the present invention comprise at least the following elements: a substrate, a first electrode and a set of one or more ferroelectric polymer elements, each of said polymer elements having at least two dimensions measuring from 5 to 1000 nm. Preferably, one of these two dimensions is the dimension perpendicular to the surface of the substrate. This dimension will also be referred to as the vertical dimension (assuming that the substrate is horizontal) or as the thickness (when the dimension perpendicular to the surface of the substrate is the smallest dimension of the element, which is usually, but not necessarily always, the case) or depth of the element). Each of these at least two dimensions ranges from 5 to 1000 nm or 10 to 1000 nm, preferably 5 to 500 nm or 10 to 500 nm, more preferably 5 to 200 nm or 10 to 200 nm, most preferably 5 to 100 nm or 10 to 100 nm. In embodiments of the present invention, the elements may form a discontinuous ferroelectric layer. This means that each element is separated to its neighboring elements as illustrated in FIGS. 15(B) and (D). In other words, a discontinuous layer of elements is an ensemble of spaced apart, discrete elements. A continuous layer does not necessarily completely covers a surface (it may presents holes going all through said layer, although this is not preferred) but it does not have two points which cannot be joined by an abstract continuous line without having to leave said layer. In FIG. 15(B), a substrate 201 is represented above which ferroelectric polymer elements (204) are disposed. An electrode, not shown, is also present covering either the whole substrate surface facing the elements or only relevant portions thereof (e.g. only under each element). In FIG. 15(D), a substrate 301 is shown comprising nanoholes. In the case of FIG. 15(D), the substrate may be considered to be or to comprise a dielectric layer (ILD layer, not shown) wherein said holes are made. Each nanohole is filled with a ferroelectric polymer, thereby defining ferroelectric elements (304). At least at the bottom of each nanoholes, a conductive layer (electrode) is present (not shown). In FIGS. 15(B) and 15(D), the elements 204 or 304 are not part of a continuous layer but, in contrast, are separated form each other. The one or more ferroelectric elements can be said to form a discontinuous ferroelectric layer or can be said to be unconnected, i.e. they do not have a layer portion connecting each element to assure the continuity between said elements. In other words, it exists on said ferroelectric layer at least two points which cannot be joined by an abstract continuous line without having to leave said ferroelectric layer. This situation wherein the elements form a discontinuous ferroelectric layer is very advantageous as it permits a very good confinement of the ferroelectric material which, in turn, is favorable for inducing the formation of one or more crystal domains orientated in such a way as to have the average direction of the crystal domains c-axis parallel to the substrate. In other embodiments of the present invention, the ferroelectric elements may form a continuous layer wherein the layer portion assuring the continuity between the ferroelectric elements has a low thickness. This thickness is advantageously as low as possible and in any case equal to maximum 20%, preferably maximum 15%, more preferably maximum 10%, even more preferably maximum 5% of the average maximum extension (i.e. dimension) V of said one or more elements measured perpendicularly to the substrate surface. This situation is represented in FIG. 15(A) and FIG. 15(C). In FIG. 15(A), a substrate 201 is shown on which a continuous ferroelectric layer is deposited, said layer consisting of elements 204 of height or depth (or maximal extension (i.e. dimension) in the direction perpendicular to the substrate) V and of a layer portion 206 connecting the ferroelectric elements 204 with each other. Also present between the ferroelectric layer and the substrate 201 is a continuous conductive layer (not shown). In FIG. 15(C), a substrate 301 is shown comprising nanoholes. In the case of FIG. 15(C), the substrate may be considered to be or to comprise a dielectric layer (ILD layer, not shown) wherein said holes are made. Each nanohole is filled with a ferroelectric polymer, thereby defining ferroelectric elements (304). At least at the bottom of each nanoholes, a conductive layer (electrode) is present (not shown). The elements are part of a ferroelectric continuous layer, wherein the continuity between the elements 304 is assured by the layer portion 306. A device as shown in FIG. 15(D) can be obtained from a device as shown in FIG. 15(C) by polishing away the layer 306.

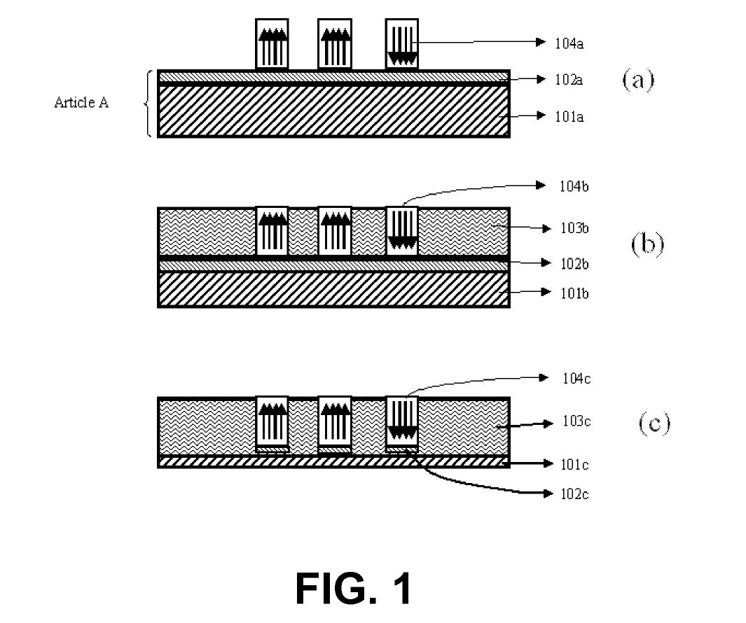

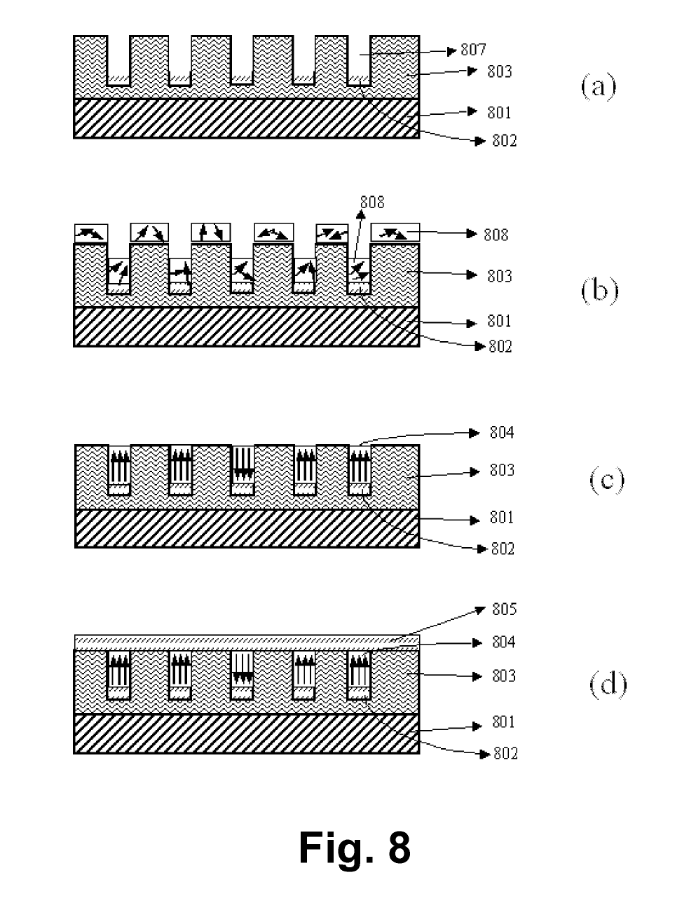

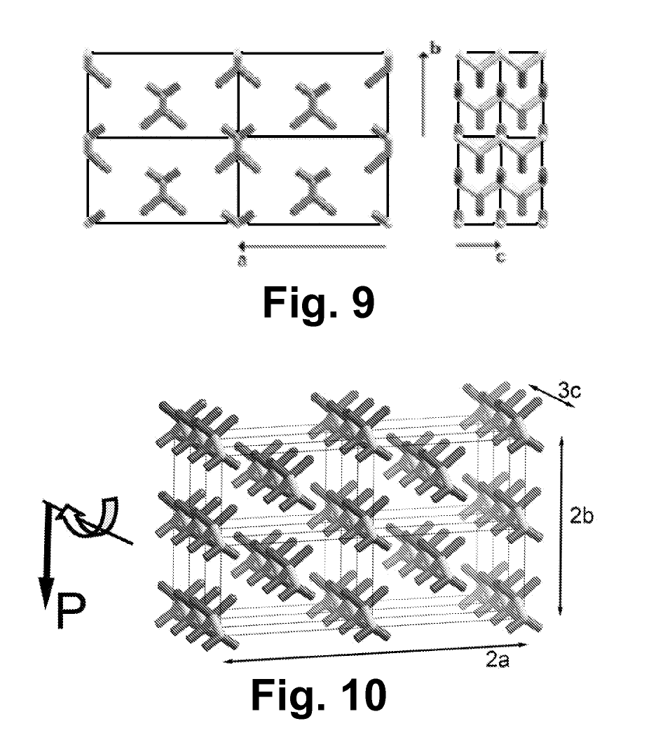

Also, the average ferroelectric dipole moment of said set is preferably oriented out of the plane of the substrate, i.e. in a non-parallel way to the substrate and preferably substantially perpendicularly to the substrate surface. Also, the axis about which the dipole moment can rotate, hereafter denoted as the chain axis or c-axis, is preferably substantially oriented parallel to the plane of the substrate, which allows for the facile orientation of the ferroelectric dipole moment perpendicularly to the substrate upon application of an electric field. For instance, a majority of, or each of the one or more ferroelectric polymer elements may have their chain axis oriented in such a way. For instance, a majority of or each of the crystal domains present in each element may have its chain axis oriented in such a way. When each element (nanostructure) consists of a single crystal, this crystal may have its chains axis oriented in such a way. For instance, in the case of P(VDF-TrFE), the polymer chains are preferably oriented in a direction which is not perpendicular to the substrate, which is preferably parallel to the substrate. Methods for obtaining such orientation will be described in the third aspect of the present invention. The substrate may be any flat surface, preferably rigid, comprising or made of an inorganic or organic material. Examples of suitable inorganic material for use in or as a substrate comprise but are not limited to a Si wafer, a Ge wafer or a glass slide among others. Suitable organic material for use in or as a substrate are preferably temperature-resistant materials, i.e. organic materials not deforming at the temperatures involved in the method according to embodiments of the present invention. In particular, such organic materials are preferably chosen among materials resisting to temperatures above the Curie temperature of the ferroelectric material used. Examples of such organic materials comprise but are not limited to polyimide (PI), polyethyleneterephthalate (PET) and polypropylene (PP), or any suitable thermosetting or thermoplastic polymer. The first electrode is made of or comprise a conductive material. It may for instance be made of a conductive metal, metal oxide or a conductive organic material. Examples of conductive metals usable in embodiments of the present invention include but are not limited to aluminum, platinum, copper, silver or gold. Examples of conductive metal oxides usable in embodiments of the present invention include but are not limited to indium-tin oxide (ITO), strontium titanate (SrTiO3), doped tin-oxide (e.g. doped with antimony) among others. Examples of conductive or semi-conductive organic material usable in embodiments of the present invention include but are not limited to polyaniline, poly(3,4-ethylenedioxythiophene)/polystyrenesulfonate (PEDOT:PSS), polythiophene, polypyrrole among others. Doping of these materials may of course be envisioned to change, e.g. to improve the conductivity. The lower electrode (see e.g. 102a in FIG. 1a) may be formed, by way of example, using well known deposition processes, such as chemical vapor deposition (CVD), sputter deposition, plasma vapor deposition (PVD), spin casting from solution, or electrochemical deposition among others. The first electrode may be a single electrode, e.g. homogeneously (e.g. uniformly) deposited on a substrate (see FIGS. 1a and 1b). In embodiments of the present invention, the electrode may be a series of conductive elements disconnected from each other. For instance, in embodiments of the present invention, the first electrode may be at the bottom of nanoholes or nanotrenches made in the substrate or preferably in a dielectric layer optionally present on said substrate (see FIG. 1c). In embodiments of the present invention, a dielectric layer, also called interlayer dielectric (ILD) may be used. In some embodiments, this layer may be placed above the first electrode (see FIG. 1b) and in some other embodiments, under the first electrode (see FIG. 1c and FIG. 8d). Non-limiting examples of dielectric materials usable in or as the dielectric layer are silicon oxide, silicon nitride, silicon carbide or dielectric polymers. The exact nature of the material(s) comprised in or making the ILD layer is not critical for the performance of the present invention and its selection lies well within the ability of the person skilled in the art. The ILD layer (see e.g. 103b in FIG. 1b) may be formed by using well known deposition processes, such as chemical vapor deposition (CVD), sputter deposition, plasma vapor deposition (PVD), electrochemical deposition or spin casting from solution among others. In embodiments of the present invention, holes (e.g. circular holes or trenches) are preferably made into the ILD layer, said holes having at least two dimensions comprised between 5 and 1000 nm or 10 and 1000 nm, preferably from 5 to 500 nm or 10 to 500 nm, more preferably 5 to 200 nm or 10 to 200 nm, most preferably 5 to 100 nm or 10 to 100 nm. Of course, if the holes are directly made in the substrate, the same constraints on the dimensions of the holes apply. To make the holes, lithography and etching techniques may be used (e.g. in a damascene process). In embodiments of the present invention, a ferroelectric polymer material may fill in at least partially said holes, thereby providing the set of one or more ferroelectric polymer nanoelements (e.g. forming a pattern), said elements having a shape and dimensions at least partly determined by the shape and the dimensions of the holes. The ferroelectric polymer elements may be made of or comprise a ferroelectric polymer. Preferably, the ferroelectric polymer elements are made of (or comprise) polymers with polar groups such as e.g. P(VDF-TrFE) copolymer. Preferably, the molar ratio of the TrFE repeating unit in the co-polymer may be in the range 20%-40%, more preferably, in the range 20%-30%. A suitable value is e.g. 25%. Also, the molar ratio of the TrFE repeating unit in the co-polymer may be 15% or more, preferably 20% or more. For instance, the molar ratio of the TrFE repeating unit in the co-polymer may be 45% or less, preferably 40% or less, more preferably 35% or less, most preferably 30% or less. Any of the values given for the lower limits may be combined with values given for the upper limits. It is well known that the ferroelectric phase of P(VDF-TrFE), which exists below the Curie transition temperature, is orthorhombic (pseudo-hexagonal), and consists of all-trans chains with their dipole moments P parallel to the crystallographic b-axis (FIG. 9, 10). FIG. 10 represents 12 crystallographic cells forming a crystal structure. 2a represents the length of the crystal (in number of cells) along the a-axis, 2b represents the length of the crystal (in number of cells) along the b-axis and 3c represents the length of the crystal (in number of cells) along the c-axis. The structure in the paraelectric phase (between the Curie transition temperature and the melting point) is hexagonal, essentially consisting of a statistical combination of trans-trans (TT) and trans-gauche (TG or TG′) rotational isomers. The paraelectric phase is similar to a nematic liquid crystal; therefore the polymer chains have a high mobility along the chain axis.

In an embodiment, to obtain the ferroelectric elements, a ferroelectric layer can first be deposited, then imprinted (e.g. stamped). The ferroelectric organic (e.g. polymeric) material may be deposited by any suitable method known to the person skilled in the art such as e.g. spin coating, drop casting or printing. In embodiments of the present invention a homogeneous layer of the ferroelectric polymer material is deposited on a first continuous electrode, in other embodiments, the ferroelectric polymer material fills the nano-holes or nano-trenches of the dielectric layer. The thickness of the ferroelectric polymer layer formed may be for instance 20 nm or more or 30 nm or more. Preferably, this thickness is 100 nm or less, 90 nm or less, 80 nm or less or 70 nm or less. For instance, the thickness can be in the range from about 30 nm to about 100 nm. A higher thickness is possible without departing from the present system. For instance, thicknesses of 120 nm or less, 150 nm or less or 200 nm or less are suitable. Any of the values given for the lower limits may be combined with values given for the upper limits. In another embodiment of the present invention, films of ferroelectric polymer material are preferably deposited on the first electrode with a thickness lower or comparable to the height of the nano-features on the mold.

In embodiments wherein holes or trenches in the substrate or dielectric layer are filled with the ferroelectric polymer material, the depth of the holes or trenches may be in the same range as indicated above for the thickness of the ferroelectric polymer layer. Devices according to the present invention comprise a set of one or more ferroelectric polymer elements, each of said one or more ferroelectric polymer elements having at least two dimensions (i.e. two out of three dimensions) (e.g. the thickness and the width) measuring from 5 to 1000 nm or 10 to 1000 nm, preferably 5 to 500 nm or 10 to 500 nm, more preferably 5 to 200 nm or 10 to 200 nm, most preferably 5 to 100 nm or 10 to 100 nm. The maximum extent of the elements in the direction perpendicular to the substrate surface (i.e. their vertical dimension when the substrate surface is horizontal, i.e. in most cases, the thickness of the ferroelectric elements) may be in the same ranges as the thickness of the layer of ferroelectric polymer material as deposited. The set of one or more ferroelectric polymer elements preferably forms a pattern, most preferably a regular pattern of constant or variable period. The set of one or more ferroelectric polymer elements may be either protruding (as in FIG. 1a) or recessing (as in FIGS. 1b and 1c). The elements are preferably similar in size and shape and are most preferably substantially the same in form and shape. The shape of the ferroelectric polymeric elements is not a limiting feature of the present invention. Preferably, the holes have walls perpendicular to the substrate surface. Non-limiting examples of suitable shapes are lines, circles, squares, rectangles, triangles, octagons, hexagons among others. In embodiments of the present invention, those shapes can be protruding. In other embodiments, they can be embedded in an ILD or the substrate. Filling in holes or trenches made in said ILD or substrate is one way to obtain such a set. The spatial distribution of the elements forming a pattern is also not very critical for the present invention but this distribution is preferably homogeneous. This distribution is preferably regular. The distance between two elements of a pattern is preferably at least 5 nm.

The lateral dimensions (length and/or width) of the nanostructure (i.e. of the elements) may be much smaller than 200 nm. It has been reported that sub-10 nm features can be fabricated by electron beam lithography and replicated by the embossing techniques (S. Y. Chou, P. R. Krauss, W. Zhang, L. Guo, L. Zhuang, J. Vac. Sci. Technol. B 1997, 15, 2897.). Electron beam lithography could therefore be used for making the mold but it is preferably not used to make directly the elements themselves. Additionally, the thickness and lateral dimensions of the patterned ferroelectric nanostructures fabricated according to the embodiments of the present invention are preferably uniform over the whole area of patterned regions. A uniformity of physical properties over the whole memory media may thus be achieved. Advantageously, each nanostructure (i.e. each element of the set) in the patterned ferroelectric polymer media may correspond to one bit of a memory device. Thus, the storage density in memory device using the ferroelectric nanostructures as storage media may be very high.

Unless provided otherwise, the P(VDF-TrFE) used in the illustrative embodiments below was obtained from Solvay and had the following characteristics: Mn=151500 g/mol, Mw=373000 g/mol, Polydispersity=2.5, intrinsic viscosity=1.22 dl/g, VDF/TrFE=70/30 mol %.

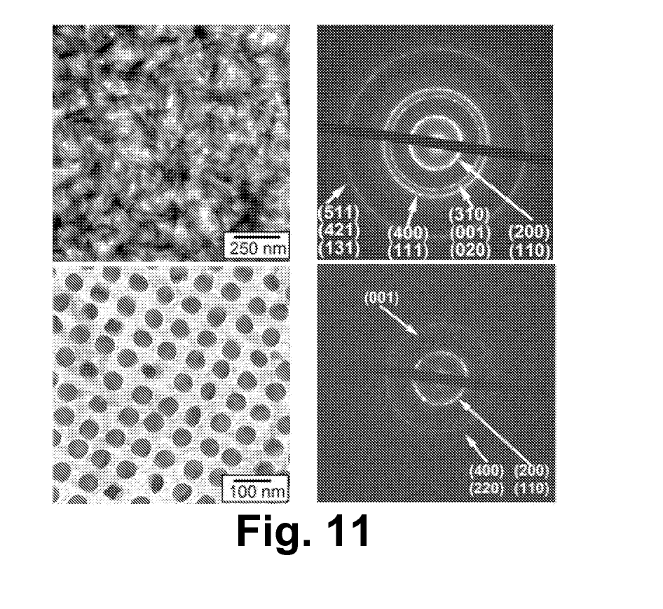

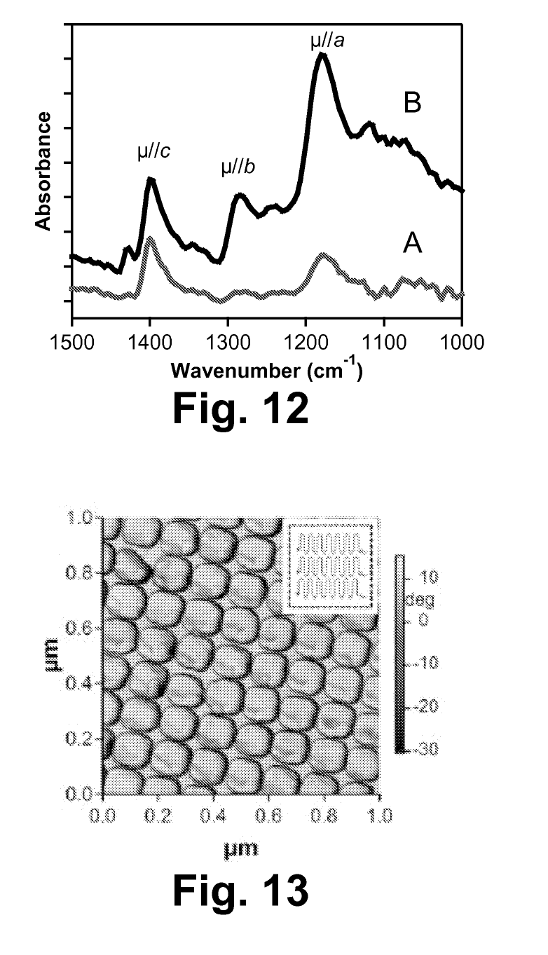

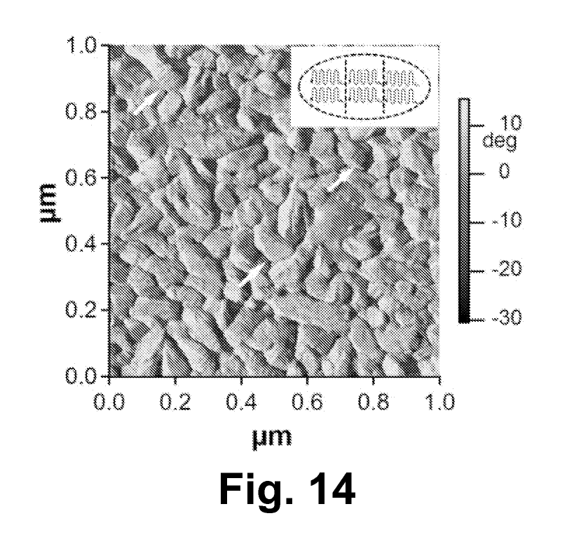

The orientation induced by the nanopatterning according to embodiments of the present invention is evidenced by the electron diffraction patterns of P(VDF-TrFE) before (FIG. 11, top right) and after the nano-embossing process (in FIG. 11, bottom right) (VDF/TrFE=70/30 mol %). The electron diffraction pattern of the continuous thin film is composed of several diffraction rings, indicating a random orientation of the crystals in the film (FIG. 11 top right). The electron diffraction was measured with a Zeiss Leo922 TEM operating at 120 keV. Silicon wafer with 300 nm thick silicon oxide was used as substrate for this purpose. Before experiments but after imprinting, a carbon thin film was evaporated onto the surface of the samples to glue (i.e. fix) nano-features in place. The continuous polymer film or the carbon-glued nano-features were subsequently floated over a diluted HF solution, following collection on TEM copper grids. Because P(VDF-TrFE) is very sensitive to electron beam exposure, a very low dose of electrons are used to obtain electron diffraction patterns. The electron beam was perpendicular to the surface of the thin films. Two or more Bragg reflections overlap in each diffraction ring, as indexed in the figure, essentially due to the pseudo-hexagonal nature of the crystal structure of the ferroelectric phase of P(VDF-TrFE). However, only two diffraction rings plus a very faint one can be observed in the electron diffraction of the P(VDF-TrFE) nanostructures obtained from the nano-embossing process according to an embodiment of the present invention. The central diffraction ring can be indexed as (200), the next strong ring is the second order of this reflection, (400), and the faint ring can be indexed as (001), according to the crystal structure of the β ferroelectric phase, showing that the a and c axes are close to being parallel to the plane of the film. The disappearance of other reflections, especially the strong (310) and (020) reflections of the second ring of the non-embossed film, indicates that the polar b-axis is tilted away from the sample plane. In the sample of FIG. 11 (bottom, left), the preferential orientation of the chain c-axis and of the polar b-axis is unambiguously confirmed by the Fourier transform infrared reflection-absorption micro-spectroscopy at normal incidence (IR) shown in FIG. 12. Fourier transform infrared reflection-absorption micro-spectroscopy was performed at normal incidence with a Continuum Microscope (Nicolet) under reflection mode. The aperture size, which is used to define the infrared beam area is 200 μm. All spectra were averages of 128 scans with 8 cm⁻¹ resolution, and were corrected for baseline. The IR spectrum of a nanoimprinted film is strongly different from the one of a continuous film processed in exactly identical conditions. This is due to dichroism, i.e., the modulation of the absorbance of specific bands depending on the preferential orientation of the polymer chains. One of the conditions for appearance of an IR band is that its transition dipole moment possesses a component parallel to the electric field. For our reflection geometry, the electric field is parallel to the plane of the substrate. The 1288 cm⁻¹ A₁ band (symmetric stretching vibration of CF₂), which has a transition dipole moment parallel to the polar b-axis, is practically extinct in the nano-embossed thin film. This indicates that the b-axis is strongly tilted away from the direction parallel to the substrate major surface in the nano-imprinted film. In contrast, the 1400 cm⁻¹ B₁ band (wagging vibration of CH₂, transition dipole moment parallel to the chain c-axis) and the 1187 cm⁻¹ B₂ band (antisymmetric stretching and rocking vibration of CF₂, transition dipole moment parallel to the a-axis) appear prominently in the nano-imprinted film, indicating an in-plane orientation of the a- and c-axes. The ratio of intensities between the A₁ and B₁ bands, I₁₂₈/I₁₄₀₀, is much smaller for the nanostructured film than for the continuous film. The combination of IR and electron diffraction thus clearly shows that the nano-embossing generates a preferential orientation of the crystal with an in-plane orientation of the a- and c-axes, and out-of-plane orientation of the b-axis. This preferential orientation of the chain axis and of the polar b axis is highly preferred for our application, because the ferroelectric dipole moment of the polymer is along the b-axis and rotates about the c-axis. Flipping of the dipole moment is thus much easier than when the crystals are randomly oriented. Generally, polymer crystals are far away from perfect. Various structural defects are included in polymer crystals grown in normal conditions. AFM experiments performed on the films shown in FIG. 11 (top, left) and FIG. 11 (bottom, left) are presented in FIGS. 14 and 13 respectively. One can see on these pictures that many grain boundaries are present in the continuous film (FIG. 14), as can also be seen in FIG. 11 (top, left). Many grains of the continuous film are actually quite small in size. In addition, within the larger grains, a fine surface texture is observed, appearing as a set of parallel lines, most probably due to the edges of stacks of very thin crystal lamellae in a close-to-edge-on orientation (arrows in FIG. 14). By contrast, in the embossed film, both TEM (FIG. 11, bottom, left) and AFM (FIG. 13) indicate that the nano-features obtained after imprinting do not show the presence of internal grain boundaries; furthermore, the texture due to the stacking of lamellae cannot be observed. This shows that the structural defects can be partially eliminated after nano-embossing and that the size and the degree of internal perfection of the crystals in the embossed nanostructure are much higher than in the continuous film. Without being bound by theory, based on the classical domain nucleation-growth mechanism, under applied voltage, reversed domains nucleate below the electrode and then elongate in the direction parallel to the electric field and simultaneously in the lateral direction until they reach an equilibrium size or meet a pinning point. Therefore, the structural defects in the crystals and grain boundaries strongly influence the polarization switching. As observed from the surface morphology, a large number of structural defects including grain boundaries and internal textures exist in the polycrystalline continuous non-embossed thin films (see FIG. 14). The various structural defects can act as pinning centers for the movement of domain walls and thus slow down the kinetics of polarization switching. Therefore, the hysteresis loop is determined by defect statistics in nucleating domains between the electrodes, and by the consequent domain size distribution during growth. In the nano-structured films, however, most structural defects are eliminated by the nano-embossing process. Therefore, the domain wall pinning by the internal structural defects and by the grain boundaries are at least partially removed. Once a reversed domain is nucleated below the top electrode, it can elongate to the bottom electrode and simultaneously expand in lateral dimensions until it reaches an equilibrium size.

Combined together, these results show that the process according to embodiments of the present invention improves crystal quality and/or size, and simultaneously orients the crystals in a favourable direction. Both factors contribute to the improvement of the ferroelectric response. An aspect of embodiments of the present invention is the use of molds, substrates or ILD layers bearing nano-features of specific dimensions to control the crystal orientation of ferroelectric polymer elements. As a result, a low coercive field of e.g. 2V is sufficient to drive those elements (i.e. to switch their polarity). As indicated in the background section, prior art technology as developed by Zhang et al only permits a coercive field of c.a. 125 MV/m. With such a high coercive field, 10 V would probably still not be enough to switch the polarity of a 100 nm film.

Embodiments of the first aspect are illustrated in FIG. 1. The three embodiments of FIG. 1 have in common that they include a substrate layer 101(a, b or c), a first electrode 102(a, b or c) established on the substrate 101(a or b) or in holes made in a ILD layer (101c), and a set of one or more (here a plurality) of ferroelectric polymer nanostructures 104(a, b or c) provided on the first electrode 102(a, b or c). The “first” electrode may be also named “lower” electrode.

Referring now to FIG. 1a and to the embodiments of the present invention illustrated therewith, a substrate layer 101a is shown on which a lower electrode 102a is established. The sum of layers 101a and 102a may be referred to as “Article A”. One or more (and in the present case a plurality) of ferroelectric polymer nanostructures 104a manufactured according to an embodiment of the present invention are established on Article A.

Referring now to FIG. 1b and to the embodiments of the present invention illustrated therewith, a lower electrode layer 102b is formed on a substrate layer 101b. On the electrode layer 102b is a first interlayer dielectric (ILD) material layer 103b. The features defined in the ILD layer 103b are cavities (i.e. holes) having at least two dimensions measuring between 10 and 1000 nm. Those cavities can therefore be called nanocavities. The sum of layers 101b, 102b, and 103b may be referred to as “Article B”. One or more (here a plurality of) ferroelectric polymer nanostructures 104b manufactured according to an embodiment of the present invention are embedded in the article of FIG. 1b (in the present case, ferroelectric polymer material is filling in the holes present in the dielectric layer, therefore forming ferroelectric polymer nanostructures, i.e. ferroelectric polymer elements having at least two dimensions measuring between 5 and 1000 nm.).

Referring now to FIG. 1c and to the embodiments of the present invention illustrated therewith, above the substrate layer 101c is an ILD layer 103c. Nanofeatures are fabricated in the ILD layer 103c, e.g. by lithography and etching techniques (e.g. a damascene process). The nanofeatures may be for instance trenches (i.e. nanotrenches) or holes (i.e. nanoholes). A lower electrode 102c is established at the bottom of nanofeatures defined in the ILD layer 103c. The formation of the lower electrode 102c may involve a polishing step for removing the conductive material deposited between the holes such as e.g. a chemical mechanical polishing (CMP) step. For instance, such a polishing step may involve the use of a slurry such as a CeO/water slurry. For instance, the first electrode may be formed using well known deposition processes as mentioned above (such as e.g. CVD, sputter deposition, PVD, electrochemical deposition or spin casting from solution or suspension) which would form a film of conductive material above the ILD layer, i.e. both in the nanostructures (e.g. holes) and between the nanostructures, followed by a polishing step to remove the conductive material present between the nanostructures. The conductive material/materials deposited on the surface of ILD layer 103c is polished away in the CMP process. One or more (here a plurality) of ferroelectric polymer nanostructures (ferroelectric elements having at least two dimensions measuring from 10 to 1000 nm) 104c manufactured according to the present invention are embedded in the article of FIG. 1c, and in particular in the dielectric layer as seen in FIG. 1c.

In embodiment of the present invention, a second electrode may be placed above the set of ferroelectric elements. This second electrode can be made of (or comprise) a conductive material selected in the same list of material as defined for the first electrode. The second electrode is may be for instance, but not limited to, an array of conducting probes permitting to address individually each ferroelectric elements.

In embodiments of the present invention, the ferroelectric organic memory device may further comprise one or more transistors. Such transistors can be used for instance to switch bits of said memory device.

In embodiments of the present invention, the ferroelectric organic memory device may further comprise means for imposing an electric field of 20 MV/m or less, preferably 15 MV/m or less, most preferably 10 MV/m or less across the device (e.g. means for imposing 3 V or less, preferably 2 V or less between the lower and the upper electrode).

In a third aspect, the present invention relates to methods for manufacturing a ferroelectric organic memory device, said device comprising a substrate, an electrode and a set of one or more ferroelectric polymer elements, each of said one or more ferroelectric polymer elements having at least two dimensions measuring from 5 to 1000 nm and wherein the chain axis of said set is oriented parallel to the substrate surface. The method is preferably performed using a semi-crystalline polymer or a liquid crystalline polymer as the ferroelectric polymer material.

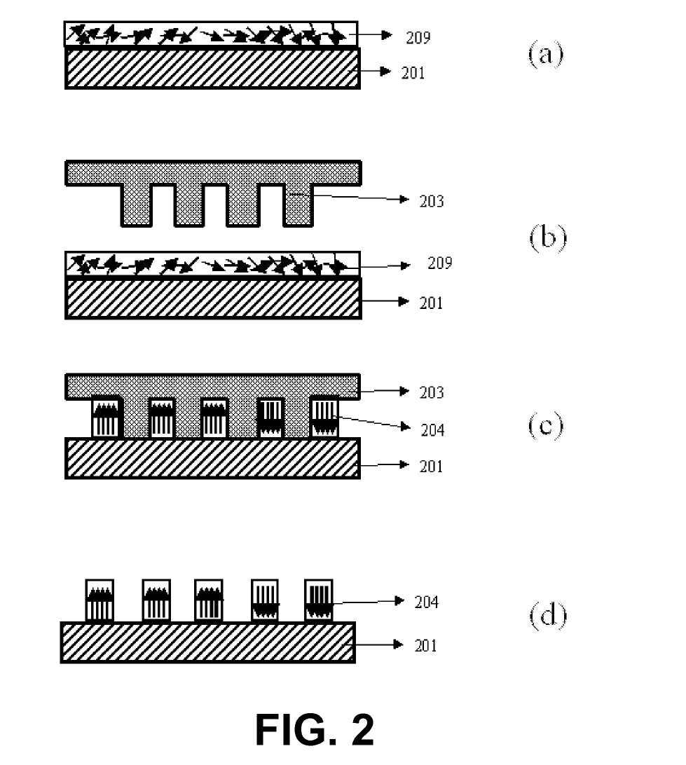

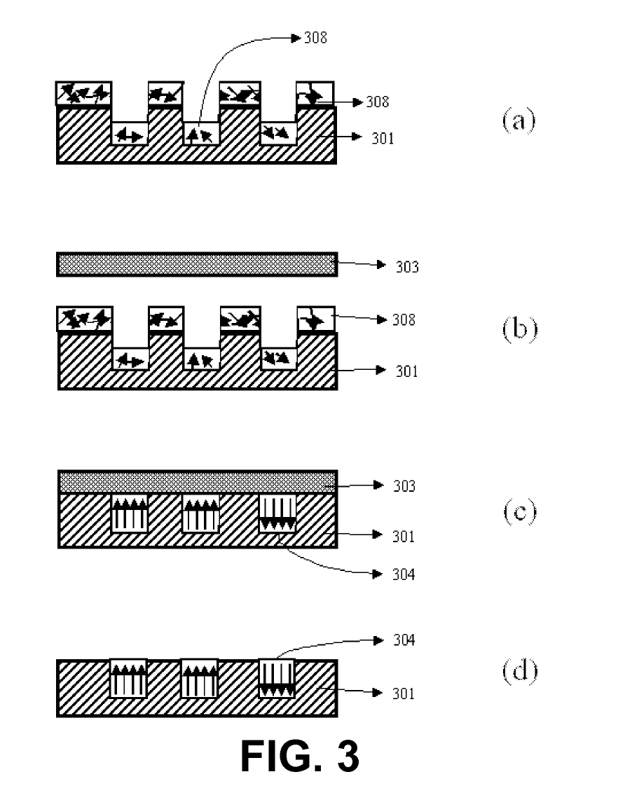

In an embodiment of the third aspect of the present invention, an embossing process is performed to fabricate the one or more (or the plurality of) ferroelectric polymer nanostructures comprised in the memory devices. The embossing process leading to a device as illustrated in FIG. 1a, is schematically shown in FIG. 2. In this embodiment, the initial thin ferroelectric polymer films may be nano-embossed and subsequently or simultaneously annealed in the paraelectric phase. Without being bound by theory we believe that isolation, confinement and/or graphoepitaxial growth of polymer crystals in separate nano-cavities as defined in the present description, results in preferential orientation of polymer chains and crystals in the ferroelectric phase after cooling.

Referring to FIG. 2a, a ferroelectric polymer material, such as for instance a P(VDF-TrFE) copolymer is deposited (e.g. spin cast, drop cast, or printed) onto Article A (201 layer in FIG. 2) (Article A including a substrate and an electrode layer), followed by drying (e.g. in vacuum at room temperature or under other suitable conditions). A preferred thickness of the formed ferroelectric polymer thin film 209 may be in the range from about 30 nm to about 100 nm. A higher thickness is possible without departing from the present system.

Referring next to FIG. 2b, a hard mold 203 bearing nanofeatures is brought into contact with the ferroelectric polymer thin film 209 on layer 201 (a substrate-first electrode assembly). The mold may be made of or comprise an inorganic or organic material such as but not limited to silicon, silicon oxide, quartz, metal, or a hard polymer. The mold may be prepared by way of example, by electron beam lithography, interference lithography or an alternative lithography technique and subsequent reactive ion etching, or by replica molding. The mold 203 may be treated with a low surface energy coating, for example, perfluorodecylsilane, to facilitate release from the ferroelectric layer after imprinting. The surface of the mold may be rich in hydrocarbon or fluorocarbon groups to facilitate release from the article in the following process.

Referring next to FIG. 2c, the mold 203 and/or the ferroelectric polymer layer are heated to a desired temperature through a heating stage. Preferably both, the mold and the ferroelectric polymer layer (e.g. via the heating of Article A) are heated. The heating of the ferroelectric polymer layer can be performed by heating Article A, i.e. via the heating of both the substrate and the ferroelectric polymer layer. The temperature of heating should be higher than the Curie temperature and lower than the melting temperature of the ferroelectric polymer material. For example, if the ferroelectric polymer material is P(VDF-TrFE), the temperature may be between 60 degrees and 150 degrees Celsius (The curie temperature and melting temperature of P(VDF-TrFE) depends on the molar ratio VDF/TRFE.). The mold 203 and Article A are subsequently pressed together under pressure for a given time. The pressure used is not highly relevant and it can be adjusted to obtain the imprinting of the wished nanofeatures in the ferroelectric polymer material layer. The pressure may be between, for example, 10 bar and 70 bar. Other pressures are possible without departing from the present invention. The mold and the ferroelectric polymer layer may be maintained under pressure between said Curie temperature and the melting temperature of the polymer material for one minute or more. There is no upper time limit but 30 minutes is usually sufficient in practice. Under the action of the mold and the temperature, the ferroelectric polymer layer will undergo a squeeze flow and an annealing process in this step. This embossing process is preferably followed by cooling the system down below the Curie temperature, and preferably to room temperature (e.g. 25° C.), while maintaining pressure until the desired temperature (e.g. room temperature) is reached. The pressure maintained during the cooling process may be different or the same as the pressure used to press the mold 203 during the heating step. Referring next to FIG. 2d, the mold 203 is then removed from the ferroelectric polymer material, thereby forming a set of one or more (e.g. a plurality of) ferroelectric polymer elements (i.e. nanostructures) (204 on the article A 201). In an embodiment the pattern formed by the set of one or more ferroelectric polymer element is the negative of the pattern present in the mold.

In another embodiment of the third aspect of the present invention, the fabrication of one or more (e.g. a plurality of) ferroelectric polymer elements having at least two dimensions measuring from 5 to 1000 nm (i.e. nanostructures) may be performed as illustrated in FIG. 3. This process may lead to a device as illustrated in FIG. 1b or 1c. The process may be named reversed embossing lithography. Instead of forming nanofeatures on the surface of a hard mold to transmit thereafter the negative of those features on the device, a plurality of nanofeatures may be defined in the dielectric layer of the device to achieve articles as described in FIGS. 1b and 1c, respectively. In an embodiment, the substrate itself is nanostructured, preferably a dielectric layer present on the substrate or on the first electrode is nanostructured.

In FIG. 3a, a solution containing the ferroelectric polymer material is applied (e.g. via spin casting or any other suitable method known to the person skilled in the art) onto the article (301) bearing the nanofeatures (i.e. onto a substrate-patterned dielectric assembly), followed by drying of residual solvent (e.g. in vacuum at room temperature or under other suitable conditions). A polymer thin film (layer 308) is thus obtained both on the upper surface of the article 301 and in the inner bottom of the nanofeatures, i.e. both in the cavities and between the cavities. A preferred thickness of the formed ferroelectric polymer layer may be as described above, e.g. in the range from about 30 nm to about 100 nm. A higher thickness is possible without departing from the present system.

Referring now to FIGS. 3b and 3c, a flat plate 303 made of hard material such as but not limited to silicon wafer, glass wafer, quartz slide, or hard thermo-resistant polymer is then pressed against the article and ferroelectric polymer thin film at elevated temperature and pressure. Of course, the flat plate may be part of a larger, not entirely flat apparatus. The temperature, pressure and thermal cycles may be the same as described for FIG. 2. The flat plate 303 may be treated with a low surface energy coating, for example, perfluorodecylsilane, to facilitate release from the article in the following process.

Referring now to FIG. 3d, after the whole system is cooled down to a temperature lower than the Curie temperature (e.g. to room temperature), the flat plate 303 is removed from the article and ferroelectric polymer material. A set of one or more ferroelectric polymer nanostructures (elements 304) is obtained and embedded in the article 301. In this situation, the upper surface of the obtained device (e.g. the memory cell) is flat.

Advantageously, the mold 203 with nanofeatures illustrated in FIG. 2 may be used for many times, while the planar plate 303 and pre-patterned articles 301 illustrated in FIG. 3 would result in improved planarity of the ferroelectric memory device.

At this point, it is possible to directly use the patterned ferroelectric polymer nanostructures for storage media. One advantage of using the patterned ferroelectric polymer nanostructures instead of a continuous thin film for memory devices is that higher storage density can be achieved.

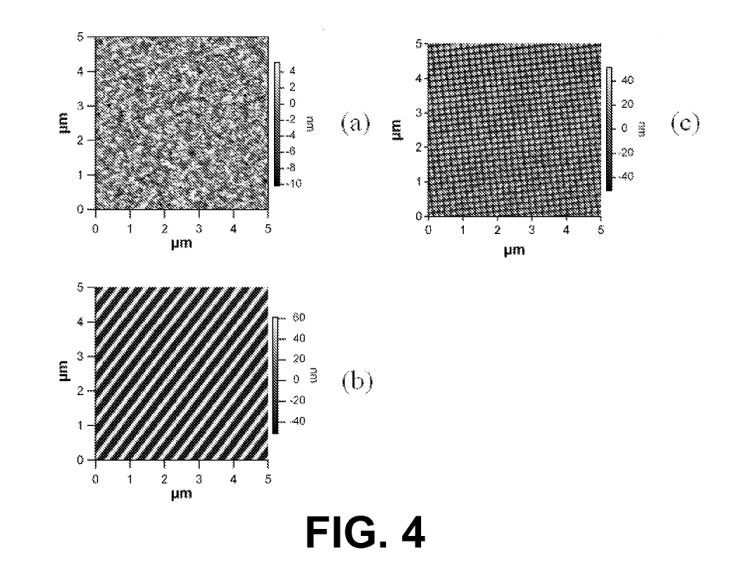

FIG. 4a shows, as a comparative example, the atomic force microscopy (AFM) topography image of a continuous P(VDF-TrFE) thin film formed on a planar article (VDF/TRFE=70/30 mol %, molar mass unknown. For this polymer, the Curie temperature is 128 degree Celsius and the melting point is 150 degree Celsius). Randomly oriented rod-like grains extending over about 50 to 200 nm can be found over the whole area in the P(VDF-TrFE) thin film annealed at 140 degree Celsius for 30 minutes. The rod-like grains can be even larger for longer annealing times. The inhomogeneity of the ferroelectric polymer thin film prevents a high memory element density with sub-200 nm line width and/or well-defined uniform operation of all cells in a given memory device.

FIGS. 4b and 4c show two examples of AFM topography images of patterned P(VDF-TrFE) nanostructures fabricated according to embodiments of the present invention. The shape and dimension of the nanostructures may be designed during fabrication of the mold or article. In FIG. 4(c), each lateral dimensions of the square elements is ˜147 nm; the lateral period of the pattern is 190 nm; and the height (i.e. the thickness) of each element is ˜97 nm. In FIG. 4(b), the lines are ˜135 nm in width; the period of the pattern is 310 nm; and the height (i.e. the thickness or vertical dimension) is ˜95 nm). For both films (b) and (c), the initial film thickness (before imprinting) was comprised between 50 and 60 nm. The depth of the recesses in the molds used to imprint the films (i.e. the height of the protrusions of the molds) was 108 nm.

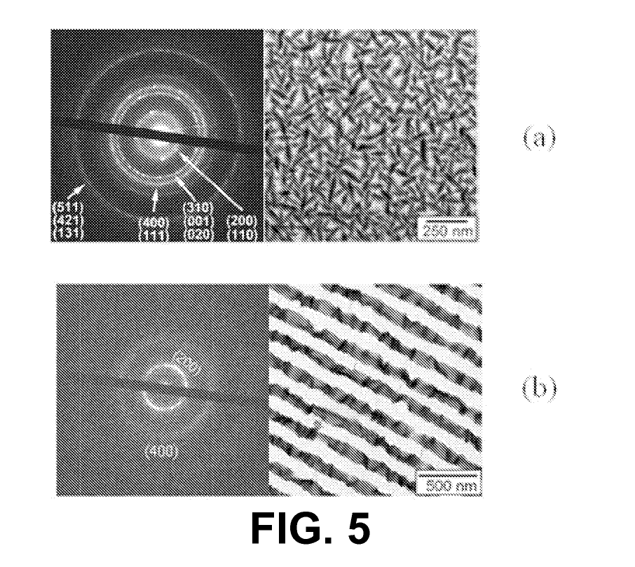

An advantage of embodiments of the third aspect of the present invention, is that the nanofeatures defined on the mold or in the dielectric layer provide an ideal confined environment for the crystallization and/or ordering of the ferroelectric polymer molecules. Heterogeneous nucleation may be suppressed by the confinement of the ferroelectric polymer material in the nanostructures. Each nanostructure may thus have a fine grain structure or may be a single crystal, and/or have few defects. Also, preferential alignment of the crystals preferably occurs during the process in such a way that the chain axis of the set of one or more ferroelectric elements is oriented parallel to the substrate surface. This is shown by the electron diffraction pattern in FIG. 5b wherein the central diffraction ring can be attributed the Miller indices (200). It is notable that diffraction patterns attributable to the Miller indices (310) and/or (020) are not present. The preferential ordering of the crystals of the P(VDF-TrFE) copolymer in FIG. 4b is thereby evidenced. A similar electron diffraction pattern is obtained for the dots (small squares) of FIG. 4c. For comparison purpose, in a spin-coated and annealed (140 degree Celsius for 30 minutes) thin film of P(VDF-TrFE) polymer of identical constitution with a thickness of 50 nm, random orientation of crystals is found (FIG. 5a wherein diffraction patterns attributable to the Miller indices (310) and/or (020) are present). However, for a film of P(VDF-TrFE) copolymer embossed for 30 min and of thickness between 50 nm and 100 nm, preferential alignment of the polar b-axis perpendicular to the substrate is achieved, giving rise to a better coupling of the ferroelectric axis to a vertically applied field. Furthermore, preferential alignment of the a axis of the crystals along lines can be further achieved as shown in FIG. 5b. Another example is shown in FIG. 11 (as discussed before).

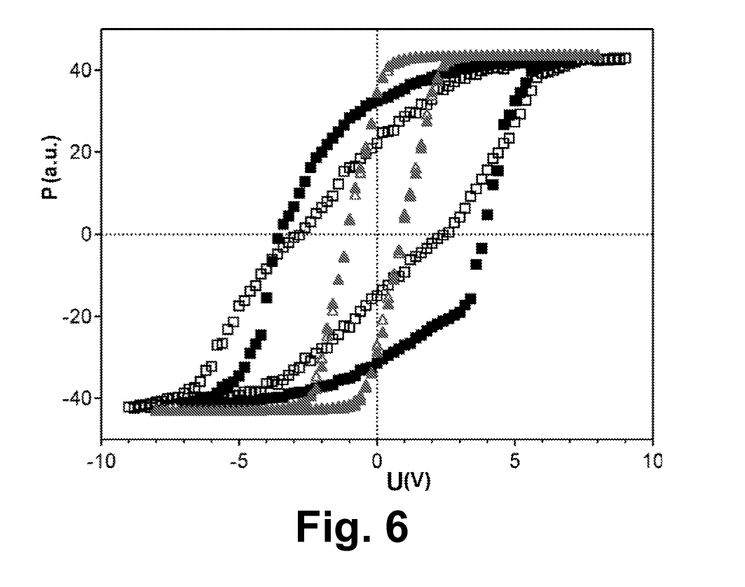

FIG. 6 shows the ferroelectric hysteresis loop of P(VDF-TrFE) ferroelectric organic memory devices manufactured according to one embodiment of the present invention (triangles), and of a P(VDF-TrFE) thin film without ferroelectric polymer elements having at least two dimensions measuring in average from 5 to 1000 nm (e.g. without embossing) (squares) for comparison, measured with piezoelectric force microscopy (PFM).

It is foreseen that patterning by use of lithographic etching methods, instead of the method according to embodiments of the present invention, would lead to a ferroelectric hysteresis loop similar to the one obtained for a thin film without ferroelectric polymer elements having at least two dimensions measuring in average from 5 to 1000 nm (e.g. without embossing). It is indeed known that etching does not improve ferroelectric properties, but deteriorates the switching behaviour. Without being bound by theory, this is believed to be due to electric leakage resulting from ion implantation (see WO 2005/064653).

The white symbols correspond to curves measured before poling. Black symbols correspond to curves measured after poling.

Nano-embossed samples according to embodiments of the present invention show ferroelectric hysteresis loops which are poling independent and which have an almost ideal square shape with a coercive voltage of 0.8V and a sharp saturation at 2.6V. The poling independence is presumably due to the very high degree of order existing already before poling in embodiments of the present invention.

The ferroelectric hysteresis loop of the comparative annealed continuous thin film is skewed and saturation of the piezoresponse (P) appears at about 7 V. The shape of the hysteresis loop is strongly changed by poling: it becomes more square but the coercive voltage simultaneously increases. The coercive voltage (V_{c}) of the spin-coated and annealed (140 degree Celsius for 30 minutes) thin film (comparative example, squares in FIG. 6) is about 2.5 Volt before poling (V_{c} is the voltage measured for a polarization of zero). With a 50 nm film thickness this indicates that the coercive field (Ec) can be calculated to be about 50 MV/m (75 MV/m after poling). The coercive voltage of the patterned P(VDF-TrFE) nanostructures according to embodiments of the present invention, however, is about 1.0 Volt (e.g 0.8 V), and with a thickness of about 100 nm (e.g. 80 nm) this indicates that the coercive field can be estimated at 10 MV/m, which is decreased by a factor of 5 compared to the coercive field of P(VDF-TrFE) continuous thin film without embossing and by a factor of at least 10 compared to the coercive field that can be calculated for the microembossed film of Zhang et al. The coercive field can be computed from the values of the coercive voltage and the thickness of the films and nanostructures, as obtained by ellipsometry and atomic force microscopy. The thickness of the nanostructures were typically around 50 nm before embossing and around 80 nm after embossing. The film before embossing (comparative) may have a lower crystal perfection and lacks a favorable preferred orientation. This is presumably the reason behind the lower performances of the non-embossed film. It should be noted that the piezoresponse hysteresis loops of P(VDF-TrFE) with similar compositions have also been measured (Bystrov, V. S., Bdikin, I. K., Kiselev, D. A., Yudin, S., Fridkin, V. M., & Kholkin, A. L. J. Phys. D: Appl. Phys. 40, 4571-4577 (2007)) in thin films prepared by Langmuir-Blodgett methods which are apparently polycrystalline. The coercive field in a 64 nm-thick thin film is about 180 MV/m, much higher than the value achieved in the nano-embossed thin films. (A commercial scanning probe microscope (Ntegra Prima, NT-MDT) was used for PFM measurements. Hysteresis loops of individual nano-cells or the continuous thin films were recorded by positioning the tip on top of a selected nano-cell or a position in the continuous thin films and monitoring the piezoresponse signal as a function of a DC bias applied to the tip. The DC bias is swept by 0.2 V increments. The piezoresponse signal is proportional to the polarization.) As is well-known to persons skilled in the art, one direction of remnant polarization state of ferroelectric materials can be used to represent a stored logic zero and the other direction of the remnant polarization state can be used to define a stored logical one. The remnant polarization state can be switched to the opposite direction by applying a switching voltage Vₛ which is higher than the coercive voltage V_{c}. As can be seen from FIG. 6, a proper switching voltage for the nanostructures of the present invention could for instance be about 2 Volt, compared to about 10 Volt for the continuous film. The reason for this lower coercive field stem from the higher degree of crystal geometries and orientation as displayed in FIGS. 4(b) (c)-5(b).

Furthermore, the polarization in the nanostructures is increased, compared to the continuous thin film without nanoembossing, as can be seen from FIG. 6. This is due to a preferred orientation of dipole moment in the nanostructures, which is parallel or anti-parallel to the normal of the substrate after the embossing process. A higher remnant polarization in the ferroelectric polymer nanostructures increases the signal-to-noise ratio in a memory device using the nanostructures as storage media (Due to the limits of the measurement method, it is not possible to obtain the real value of the remnant polarization. In fact, currently PFM is the only method for measuring the hysteresis loop at the nanoscale, and developing an alternate method would be very time-expensive.).

In embodiments of the third aspect of the present invention, solvent annealing can be used alone or in combination with thermal annealing. When solvent annealing is used, the then optional simultaneous or prior or following thermal annealing can either be performed as in other embodiments where solvent annealing is not used, e.g. by bringing the mold (or the flat plate) and/or the ferroelectric polymer to a temperature higher than the Curie temperature of said ferroelectric polymer layer but lower than the melting temperature of said ferroelectric polymer layer, or it can be performed at a lower temperature, e.g. by bringing the mold (or the flat plate) and/or the ferroelectric polymer to a temperature higher than room temperature but lower than the melting temperature of said ferroelectric polymer layer. Alternatively, the mold (or flat plate) and/or the ferroelectric polymer is not heated during solvent annealing.

The solvent is preferably chosen for its ability to assist molecular rearrangement after diffusing into the organic semiconductor film. Solvent annealing conditions are selected to provide molecular rearrangement that favour the orientation of the chain axis of the elements of the set parallel to the substrate surface (while preferably avoiding conditions that damage the layer). Solvent annealing conditions in some embodiments are determined by systematically varying the solvent temperature, the ferroelectric polymer layer temperature and/or the mold (or plate) temperature, and the annealing time until an appropriate level of improvement in electrical properties is obtained.

In embodiments, a portion of a solvent is vaporized to bring the vapor into contact with the ferroelectric polymer. The chemical potential of the vapor molecules is preferably controlled to provide an interaction with the polymer film to alter the molecular arrangement of the film. Some embodiments further entail placing the substrate (with the first electrode and the ferroelectric polymer layer) on a first temperature controlled stage and placing the solvent on a second temperature controlled stage. The chemical potential of the vapor can be adjusted by controlling the temperature of the solvent. Appropriate solvent annealing conditions may be obtained by adjusting the temperature of the solvent, the substrate, the mold/plate and the solvent anneal time.

Suitable solvents are for instance cyclohexanone, gamma-butyrolactone, ethylene carbonate, N-methyl pyrrolidone, dimethylsulfoxide, dimethylacetamide, dimethylformamide, acetone among others.

Solvent annealing may permit to anneal the film below the Curie temperature of the ferroelectric polymer or may be used in addition to a thermal annealing step occurring above the Curie temperature but below the melting temperature of the polymer.

By selecting appropriate solvent annealing conditions, the presence of solvent in the polymer layer contributes to a desirable rearrangement of the molecular structure of a relatively poor, as-deposited ferroelectric polymer layer.

By selecting an appropriate chemical potential for the vapor, temperature for the ferroelectric polymer, and annealing time, optimized improvement of molecular order via molecular rearrangement is obtained. In general, two alternatives are a consequence of inappropriate selection of annealing conditions. Firstly, inappropriate conditions can lead to insubstantial changes in molecular structure and related insubstantial improvements in electrical properties. This situation can occur, for example, when the chemical potential of the vapor is too low and insufficient vapor molecules enter the ferroelectric polymer. Secondly, inappropriate conditions can lead to excessive molecular rearrangements and potential degradation in electrical properties of the organic semiconductor film. Too high a chemical potential of the vapor, for example, can lead to excessive entry of vapor molecules into the ferroelectric polymer and gross changes in structure

In one embodiment, optimum solvent annealing conditions are determined empirically. For example, for a particular ferroelectric polymer and solvent pair, substrate temperature, vapor chemical potential, and annealing time are systematically varied, using samples of the particular ferroelectric polymer. Devices comprising said samples are made and characterised and an optimum or preferable annealing condition is determined.

Varying the chemical potential of the vapor will typically vary the density of solvent molecules in the ferroelectric polymer. In some embodiments, the combination of varying the chemical potential of the vapor and selecting an appropriate annealing time can suffice to provide a preferable annealing condition. In other embodiments, varying the temperature of the ferroelectric polymer is also useful in obtaining desirable molecular rearrangements and a preferable annealing condition.

Further considerations can assist in appropriate selection and use of a solvent. In some embodiments, solvents with an appreciable vapor pressure relative to other solvents are considered for use during annealing. Generally, the chemical potential must be high enough so that sufficient solvent molecules enter the ferroelectric polymer to enable desirable molecular rearrangements. Conversely, the chemical potential must not be so high as to lead to undesirable molecular rearrangements, for example, gross disordering. In particular, too high a chemical potential can also lead to dewetting of the ferroelectric polymer. In one embodiment, the chemical potential of the vapor 120 is controlled by selecting a solvent temperature in a range of about 0° C. to about 50° C.

To sum up, by using embodiments of the method according to the present invention one obtains a plurality of P(VDF-TrFE) nanostructures with excellent ferroelectric properties including a lower coercive field than obtained for non-structured films, and higher signal-to-noise ratio than obtained for non-structured films, enabling a trouble-free electrical probing of the polarization states and behavior of the memory media. This result can be generalised to other ferroelectric polymer materials.

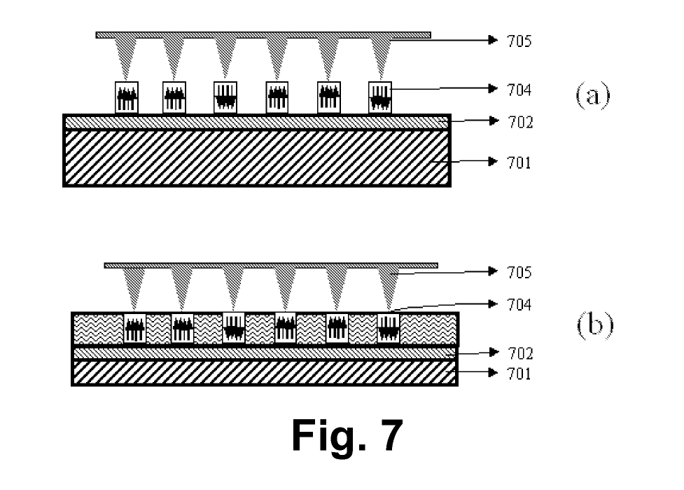

Further processing can be carried out to manufacture a real ferroelectric memory device. After the formation of a plurality of ferroelectric polymer nanostructures, manufactured according to embodiments of the present invention, a second or upper electrode may then be formed as set forth herein. In a probe-base memory device, the upper electrode may be an array of conducting probes, as illustrated in FIG. 7, for instance a micro-electro-mechanical system (MEMS). The ferroelectric polymer nanostructures can either be embossed on the planar article (FIG. 7a, protruding elements) or be embedded in the article (FIG. 7b, recessed elements), according to embodiments of the present invention.

As described above, in the method of manufacturing patterned ferroelectric polymer nanostructures according to the present invention, a patterned ferroelectric storage media having excellent physical properties can be formed. FIG. 8 illustrates another embodiment of a memory device using a plurality of patterned ferroelectric polymer nanostructures as storage media after further processing as set forth herein. As noted previously for the Article of FIG. 1c, a first ILD layer 803 is formed on a substrate 801 by using known deposition processes, followed by a structuring process (e.g. a damascene process) involving for instance lithography and etching techniques. Nanofeatures 807 such as nanotrenches or nanoholes may be defined in the ILD layer 803 by lithography and etching. Thereafter, a first or lower electrode 802 is deposited onto the ILD layer 803, followed by CMP or any other polishing process, in order to polish away the conductive material on the surface of ILD layer to yield an electrode layer comprising a plurality of electrodes as shown in FIG. 8a. Thereafter, as seen in FIG. 8b, a layer of ferroelectric polymer material 808 is deposited onto the layers 802 and 803 as shown. The ferroelectric material 808 may be deposited using well known spinning techniques. Referring next to FIG. 8c, the ferroelectric polymer material 808 is pushed in the recessed pattern according to an embodiment of the present invention to yield ferroelectric polymer nanostructures 804 embedded in Article C. Referring next to FIG. 8d, a second or upper electrode 805 is deposited onto layers 803 and 804 by a PVD, CVD or spin casting process that is sensitive to preserving the physical qualities of the ferroelectric polymer nanostructures, followed by etching as is known in the art. Thus, second electrode 805 may also be an electrically conductive material like the first electrode 802, and can be patterned to allowing addressing a single ferroelectric nanostructures.

In another aspect, the present invention relates to an array of ferroelectric organic memory devices.

In another aspect, the present invention relates to the use of ferroelectric organic memory devices with a driving field of 20 MV/m or less, preferably 15 MV/m or less, most preferably 10 MV/m or less. In an embodiment, the present invention relates to the use of a driving signal lower than 3 V and preferably lower than 2 V (in absolute value) for switching an polymer ferroelectric layer, e.g. a ferroelectric having a thickness of 100 nm.

In another aspect, the present invention relates to a method of driving a ferroelectric organic memory device comprising the steps of providing a ferroelectric organic memory device as described in any of the embodiments above and imposing a driving field of 20 MV/m or less, preferably 15 MV/m or less, most preferably 10 MV/m or less across at least part of said device.

Writing data can be achieved by applying an electrical voltage so that the field across the ferroelectric element exceed its coercive field, wherein said coercive field is 20 MV/m or less, preferably 15 MV/m or less, most preferably 10 MV/m or less. For example, +2 or −2 Volt, can be applied on the conducting probes. The ferroelectric domains in the nanostructures are oriented with respect to the electric field between the second electrode (e.g. the conducting probe) and the lower (first) electrode. After the applied voltage is switched off, the orientation of the ferroelectric domain in the nanostructures is maintained. Electric charges are generated on the surface of the nanostructures according to the remnant polarization. The electric charges on the surface of the nanostructures create a depletion or accumulation region at the end of the probe, depending on their polarity. Reading data in the probe-based memory device can be achieved by applying a predetermined electric voltage, for example, 0.8 Volt, and measuring a variation of capacitance or resistance, due to the formation of depletion or accumulation electric charges on the probe.

As described above, in the method of manufacturing a patterned ferroelectric polymer medium according to the present invention, a plurality of nanostructures having less defects can be formed. In addition, the ferroelectric performance in the nanostructures can be highly improved compared to a continuous thin film. The present invention can be applied to the manufacture of different memory devices.

Other arrangements for accomplishing the objectives embodying the invention will be obvious for those skilled in the art.

It is to be understood that although preferred embodiments, specific constructions and configurations, as well as materials, have been discussed herein for devices according to the present invention, various changes or modifications in form and detail may be made without departing from the scope and spirit of this invention. For example, any formulas given above are merely representative of procedures that may be used. Functionality may be added or deleted from the block diagrams and operations may be interchanged among functional blocks. Steps may be added or deleted to methods described within the scope of the present invention.

1-25. (canceled)

26. A ferroelectric organic memory device comprising:
a non-ferroelectric substrate,
a first electrode, and
a set of one or more ferroelectric polymer elements; wherein said set of one or more ferroelectric polymer elements either:
forms a discontinuous ferroelectric layer, or
forms part of a continuous ferroelectric layer comprising said set of one or more ferroelectric elements and a portion assuring a layer continuity between said one or more ferroelectric polymer elements;
wherein said portion has an average thickness T representing maximally 20% of the average height or depth V of said one or more ferroelectric polymer elements;
wherein said one or more ferroelectric polymer elements has at least two dimensions measuring on average from 5 to 1000 nm; and
wherein the average orientation of the chain axis of the elements of the set is substantially parallel to the substrate surface.

27. The device according to claim 26, wherein said one or more elements forms a pattern of fixed or variable period.

28. The device according to claim 26, wherein a ferroelectric hysteresis loop of said device has a coercive field of 20 MV/m or less.

29. The device according to claim 26, wherein each of said one or more ferroelectric polymer elements has at least two dimensions measuring from 5 to 500 nm.

30. The device according to claim 26, wherein one of said at least two dimensions is the height or depth V.

31. The device according to claim 26, wherein said one or more ferroelectric polymer elements comprises a semi-crystalline or liquid crystalline polymer.

32. The device according to claim 31, wherein said semi-crystalline polymer comprises a copolymer of vinylidene fluoride and trifluoroethylene.

33. The device according to claim 32, wherein said copolymer comprises from 20 to 40 mol % of trifluoroethylene.

34. The device according to claim 32, wherein the ratio of the A1 absorbance band to the B1 absorbance band in an FT-IR reflection-absorption spectrum of said set is larger than 2.

35. The device according to claim 26, wherein a dipolar moment of said one or more ferroelectric polymer elements is reversible in 1 μs or less.

36. The device according to claim 26, wherein all of said one or more ferroelectric polymer elements have substantially the same dimensions.

37. The device according to claim 26, wherein each of said one or more ferroelectric polymer elements comprises a single crystal.

38. The device according to claim 26, wherein said first electrode forms a continuous and homogeneous layer on said substrate.

39. The device according to claim 26, further comprising a dielectric layer.

40. The device according to claim 39, wherein said dielectric layer comprises holes having at least two dimensions measuring from 5 to 1000 nm.

41. The device according to claim 39, wherein said holes extend through the whole thickness of said dielectric layer.

42. The device according to claim 26 further comprising one or more transistors.

43. A method for manufacturing a ferroelectric organic memory device, said method comprising the steps of:
providing a non-ferroelectric substrate,
applying a conductive material on said non-ferroelectric substrate, and
forming a set of one or more ferroelectric polymer elements onto said conductive material;
wherein said step of forming a set of one or more ferroelectric polymer elements comprises the steps of either:
(i) applying a ferroelectric polymer layer onto at least part of said conductive material, and
bringing a mold comprising elements having at least two dimensions measuring from 5 to 1000 nm and/or said ferroelectric polymer layer to a temperature higher than the Curie temperature of said ferroelectric polymer layer but lower than the melting temperature of said ferroelectric polymer layer; or.
(ii) applying a ferroelectric polymer layer onto at least part of said conductive material, and
solvent annealing said polymer layer before or during said forming of said set, and
optionally heating up a mold comprising elements having at least two dimensions measuring from 5 to 1000 nm and/or said ferroelectric polymer layer to a temperature higher than room temperature but lower than the melting temperature of said ferroelectric polymer layer;
wherein said step of forming a set of one or more ferroelectric polymer elements further comprises the steps of:
pressing said mold into said ferroelectric polymer layer;
setting the temperature of said mold and/or said ferroelectric polymer material to a temperature lower than the Curie temperature of said ferroelectric material; and
removing said mold from said ferroelectric polymer material, thereby providing a device comprising said set of one or more ferroelectric elements, said ferroelectric elements having at least two dimensions measuring from 5 to 1000 nm onto said conductive material wherein said set of one or more ferroelectric polymer elements either:
forms a discontinuous ferroelectric layer, or
forms part of a continuous ferroelectric layer comprising said set of one or more ferroelectric elements and a portion assuring a layer continuity between said one or more ferroelectric polymer elements;
wherein said portion has an average thickness T representing maximally 20% of the average height or depth V of said one or more ferroelectric polymer elements.

44. A method for manufacturing a ferroelectric organic memory device, said method comprising the steps of:
providing a non-ferroelectric substrate;
optionally applying a conductive material on said non-ferroelectric substrate;
forming a dielectric layer onto said non-ferroelectric substrate or onto said conductive material and making holes into said dielectric layer, said holes having at least two dimensions comprised between 5 and 1000 nm;
if no conducting material has been applied yet, forming a layer of conductive material into said holes; and
forming a set of one or more ferroelectric polymer elements onto said conductive material, wherein said step of forming a set of one or more ferroelectric polymer elements comprises:
forming a ferroelectric polymer thin film on the dielectric layer comprising said holes;
wherein said step of forming a set of one or more ferroelectric polymer elements further comprises the steps of either:
(i) pressing a flat plate onto the ferroelectric polymer thin film, wherein the temperature of the plate and/or the film is above the Curie temperature of the ferroelectric polymer but below the melting point of the ferroelectric polymer; or
(ii) solvent annealing said polymer layer before or during said forming of said set, and pressing a flat plate onto the ferroelectric polymer thin film, wherein the temperature of the plate and/or the film is at or above room temperature but below the melting point of the ferroelectric polymer;
wherein said step of forming a set of one or more ferroelectric polymer elements further comprises the steps of:
setting the temperature of the plate and ferroelectric polymer material below the Curie temperature; and
removing the plate from the ferroelectric polymer material to provide said set, thereby forming a set of one or more ferroelectric polymer elements having at least two dimensions measuring from 5 to 1000 nm onto said conductive material, wherein said set of one or more ferroelectric polymer elements either:
forms a discontinuous ferroelectric layer, or
forms part of a continuous ferroelectric layer comprising said set of one or more ferroelectric elements and a portion assuring a layer continuity between said one or more ferroelectric polymer elements;
wherein said portion has an average thickness T representing maximally 20% of the average height or depth V of said one or more ferroelectric polymer elements.

45. A method of driving a ferroelectric organic memory device comprising the steps of:
providing a ferroelectric organic memory device comprising:
a substrate, and
a set of one or more ferroelectric polymer elements, each of said one or more ferroelectric polymer elements having at least two dimensions measuring from 5 to 1000 nm;
wherein said elements either:
form a discontinuous ferroelectric layer, or
form part of a continuous ferroelectric layer comprising said set of one or more ferroelectric elements and a portion assuring a layer continuity between said one or more ferroelectric polymer elements;
wherein said portion (206, 306) has an average thickness T representing maximally 20% of the average height or depth V of said one or more ferroelectric polymer elements; and
imposing a driving field of 20 MV/m or less across at least part of said device.
